(19) United States
(12) Patent Application Publication
(10) Pub. No.: US 2024/0371766 A1
(43) Pub. Date: Nov. 7, 2024

(54) SILICON CARBIDE SEMICONDUCTOR DEVICE

(71) Applicant: SUMITOMO ELECTRIC INDUSTRIES, LTD., Osaka (JP)

(72) Inventors: Kosuke UCHIDA, Osaka (JP); Yu SAITOH, Osaka (JP)

(21) Appl. No.: 18/293,460

(22) PCT Filed: Jun. 21, 2022
(86) PCT No.: PCT/JP2022/024785

§ 371 Date: Jan. 30, 2024

(30) Foreign Application Priority Data
Sep. 15, 2021 (JP) 2021-150122

(51) Int. Cl. H01L 23/528; H01L 27/088; H01L 29/06; H01L 29/16; H01L 29/40; H01L 29/423; H01L 29/78

(52) U.S. Cl. CPC H01L 23/5286; H01L 27/088; H01L 29/0623; H01L 29/408; H01L 29/1608; H01L 29/4236; H01L 29/7813

(57) ABSTRACT

A silicon carbide semiconductor device includes a silicon carbide substrate having a first principal surface; an interlayer insulating film; and a gate pad and a source pad provided on the film. The silicon carbide substrate includes a first region including unit cells; a second region overlapping the gate pad; and a third region. Each unit cell includes a drift region; a body region; a source region; a contact region; a gate electrode; and a gate insulating film. The second region includes a first semiconductor region. The third region includes a second semiconductor region. The first semiconductor region and the second semiconductor region are contiguous. In the interlayer insulation film, first and second contact holes are formed. The source pad is electrically connected to the source region and the contact region, electrically connected to the second semiconductor region.

### TECHNICAL FIELD

The present disclosure relates to a silicon carbide semiconductor device.

The present application claims priority to Japanese Application No. 2021-150122 filed on Sep. 15, 2021, and the entire contents of the Japanese Application are incorporated herein by reference.

### BACKGROUND ART

A silicon carbide semiconductor device that has an object to suppress dielectric breakdown of an insulating film under a gate pad is disclosed (e.g., Patent Document 1).

### RELATED ART DOCUMENTS

### Patent Documents

Patent Document 1: WO2018/055719

### SUMMARY OF THE INVENTION

A silicon carbide semiconductor device in the present disclosure includes:
a silicon carbide substrate having a first principal surface;
an interlayer insulating film covering the first principal surface; and
a gate pad and a source pad provided on the interlayer insulating film,
wherein the silicon carbide substrate includes, in plan view in a direction perpendicular to the first principal surface,
   a first region including a plurality of unit cells,
   a second region overlapping the gate pad, and
   a third region contiguous to the second region,
wherein each of the plurality of unit cells includes
   a drift region having a first conductive type,
   a body region having a second conductive type different from the first conductive type,
   a source region provided on the first principal surface, separated from the drift region by the body region, and having the first conductive type,
   a contact region provided on the first principal surface, electrically connected to the body region, and having the second conductive type,
   a gate electrode electrically connected to the gate pad, and
   a gate insulating film provided between the gate electrode and the drift region, the body region, and the source region,
wherein the second region includes a first semiconductor region having the second conductive type,
wherein the third region includes a second semiconductor region having the second conductive type,
wherein the first semiconductor region and the second semiconductor region are contiguous to each other on the first principal surface,
wherein, in the interlayer insulation film, a first contact hole reaching the source region and the contact region, and a second contact hole reaching the second semiconductor region are formed, and
wherein the source pad is electrically connected to the source region and the contact region via the first contact hole,
   electrically connected to the second semiconductor region via the second contact hole, and
   in a cross section as viewed in a direction parallel to the first principal surface, a second dimension in a short direction of the second contact hole is greater than a first dimension in a short direction of the first contact hole.

### BRIEF DESCRIPTION OF THE DRAWINGS

FIG. 1 is a top view illustrating a silicon carbide semiconductor device according to a first embodiment;

FIG. 2 is a diagram illustrating respective regions in a silicon carbide substrate in the silicon carbide semiconductor device according to the first embodiment;

FIG. 3 is a top view illustrating a region 221 in FIGS. 1 and 2 in perspective view of a passivation film, a gate pad, and a source pad;

FIG. 4 is a top view illustrating a configuration of a first principal surface of the silicon carbide substrate in the region 221 in FIGS. 1 and 2;

FIG. 5 is a top view illustrating a region 222 in FIGS. 1 and 2 in perspective view of a passivation film, a gate pad, and a source pad;

FIG. 6 is a top view illustrating the region 222 in FIGS. 1 and 2 in perspective view of a passivation film, a gate pad, and a source pad;

FIG. 7 is a cross-sectional view illustrating a silicon carbide semiconductor device according to the first embodiment;

FIG. 8 is a cross-sectional view illustrating a configuration of a unit cell;

FIG. 9 is a cross-sectional view illustrating a silicon carbide semiconductor device according to a second embodiment;

FIG. 10 is a top view illustrating a silicon carbide semiconductor device according to a third embodiment;

FIG. 11 is a diagram illustrating respective regions in a silicon carbide substrate in the silicon carbide semiconductor device according to the third embodiment;

FIG. 12 is a cross-sectional view (part 1) illustrating the silicon carbide semiconductor device according to the third embodiment;

FIG. 13 is a cross-sectional view (part 2) illustrating the silicon carbide semiconductor device according to the third embodiment;

FIG. 14 is a top view illustrating a silicon carbide semiconductor device according to a fourth embodiment;

FIG. 15 is a diagram illustrating respective regions in a silicon carbide substrate in the silicon carbide semiconductor device according to the fourth embodiment;

FIG. 16 is a cross-sectional view illustrating the silicon carbide semiconductor device according to the fourth embodiment;

FIG. 17 is a top view illustrating a silicon carbide semiconductor device according to a fifth embodiment;

FIG. 18 is a diagram illustrating respective regions in a silicon carbide substrate in the silicon carbide semiconductor device according to the fifth embodiment;

FIG. 19 is a top view illustrating a silicon carbide semiconductor device according to a sixth embodiment;

FIG. 20 is a diagram illustrating respective regions in a silicon carbide substrate in the silicon carbide semiconductor device according to the sixth embodiment;

FIG. 21 is a top view illustrating a silicon carbide semiconductor device according to a seventh embodiment;

FIG. 22 is a diagram illustrating respective regions in a silicon carbide substrate in the silicon carbide semiconductor device according to the seventh embodiment;

FIG. 23 is a top view illustrating a silicon carbide semiconductor device according to an eighth embodiment;

FIG. 24 is a top view illustrating a configuration of a first principal surface of a silicon carbide substrate in a region 223 in FIG. 23;

FIG. 25 is a cross-sectional view (part 1) illustrating the silicon carbide semiconductor device according to the eighth embodiment;

FIG. 26 is a cross-sectional view (part 2) illustrating the silicon carbide semiconductor device according to the eighth embodiment;

FIG. 27 is a cross-sectional view (part 3) illustrating the silicon carbide semiconductor device according to the eighth embodiment; and

FIG. 28 is a top view illustrating a modified example of a first region.

### EMBODIMENTS FOR CARRYING OUT THE INVENTION

### Problems to be Solved by the Present Disclosure

In the silicon carbide semiconductor device described in Patent Document 1, electric field concentration tends to occur in an interlayer insulating film when a surge occurs. Such electric field concentration may lead to breakdown.

The present disclosure has an object to provide a silicon carbide semiconductor device that can alleviate electric field concentration in an interlayer insulating film.

### Effect in the Present Disclosure

According to the present disclosure, electric field concentration of an interlayer insulating film can be alleviated.

Embodiments will be described in the following.

### DESCRIPTION OF EMBODIMENTS OF THE PRESENT DISCLOSURE

First, embodiments in the present disclosure are enumerated and described. In a crystallographic description in the present description and in the drawings, an individual orientation is denoted by [ ], a collective orientation is denoted by < >, an individual plane is denoted by ( ) and a collective plane is denoted by { }. In addition, although a negative crystallographic index is normally expressed by adding a ‘-’ (bar) above the numeral, in the present specification, a negative sign is added before the numeral.
[1] A silicon carbide semiconductor device according to an aspect in the present disclosure includes:
   a silicon carbide substrate having a first principal surface;
   an interlayer insulating film covering the first principal surface; and
   a gate pad and a source pad provided on the interlayer insulating film,
   wherein the silicon carbide substrate includes, in plan view in a direction perpendicular to the first principal surface,
      a first region including a plurality of unit cells,
      a second region overlapping the gate pad, and
      a third region contiguous to the second region,
   wherein each of the plurality of unit cells includes
      a drift region having a first conductive type,
      a body region having a second conductive type different from the first conductive type,
      a source region provided on the first principal surface, separated from the drift region by the body region, and having the first conductive type,
      a contact region provided on the first principal surface, electrically connected to the body region, and having the second conductive type,
      a gate electrode electrically connected to the gate pad, and
      a gate insulating film provided between the gate electrode and the drift region, the body region, and the source region,
   wherein the second region includes a first semiconductor region having the second conductive type,
   wherein the third region includes a second semiconductor region having the second conductive type,
   wherein the first semiconductor region and the second semiconductor region are contiguous to each other on the first principal surface,
   wherein, in the interlayer insulation film, a first contact hole reaching the source region and the contact region, and a second contact hole reaching the second semiconductor region are formed, and
   wherein the source pad is electrically connected to the source region and the contact region via the first contact hole,
      electrically connected to the second semiconductor region via the second contact hole, and
      in a cross section as viewed in a direction parallel to the first principal surface, a second dimension in a short direction of the second contact hole is greater than a first dimension in a short direction of the first contact hole.

The third region contiguous to the second region is provided, and the first semiconductor region and the second semiconductor region are contiguous on the first principal surface. In addition, in a cross section as viewed in a direction parallel to the first principal surface, the second dimension in the short direction of the second contact hole is greater than the first dimension in the short direction of the first contact hole. Therefore, the contact resistance between the source pad and the second semiconductor region can be reduced, and even if a surge occurs, electric field concentration on the interlayer insulating film in the second region can be reduced.
[2] In [1], the silicon carbide semiconductor may be configured such that the contact region and the second semiconductor region are contiguous to each other on the first principal surface.
In this case, it is easy to control the contact region and the second semiconductor region at the same potential.
[3] In [1] or [2], the silicon carbide semiconductor may be configured to further include:
   an active region including the plurality of unit cells; and
   a terminal region provided around the active region,
   wherein the terminal region includes a third semiconductor region having the second conductive type,
   wherein, in plan view in a direction perpendicular to the first principal surface, the second semiconductor region is provided between the gate pad and the terminal region, and includes a fourth semiconductor region contiguous to the first semiconductor region and the third semiconductor region on the first principal surface,
   wherein a concentration of impurities of the second conductivity type in the third semiconductor region is lower than a concentration of impurities of the second conductivity type in the fourth semiconductor region, and
   wherein the second contact hole includes a third contact hole reaching the fourth semiconductor region.
In this case, the electric field concentration on the interlayer insulating film can be alleviated.
[4] In [3], the silicon carbide semiconductor may be configured to further include:
   a field insulating film provided between the interlayer insulating film and the first semiconductor region, the fourth semiconductor region, and the third semiconductor region,
   wherein a fourth contact hole reaching the fourth semiconductor region is formed in the field insulating film,
   wherein the interlayer insulation film is in contact with the fourth semiconductor region inside the fourth contact hole, and
   wherein the third contact hole is positioned inside the fourth contact hole.
In this case, the electric field concentration on the interlayer insulating film can be further alleviated.
[5] In [3] or [4], the silicon carbide semiconductor may be configured to further include:
   a source runner electrically connected to the source pad, and electrically connected to the fourth semiconductor region through the third contact hole,
   wherein, in a cross section as viewed in a direction parallel to the first principal surface, a side surface of the source runner on a side away from the gate pad is positioned on a boundary line between the third semiconductor region and the fourth semiconductor region, or positioned closer to the gate pad as compared to the boundary line. In this case, the electric field concentration on the interlayer insulating film below the source runner can be easily alleviated.
[6] In any one of [3] to [5], the silicon carbide semiconductor may be configured to further include:
   a first gate runner electrically connected to the gate pad, extending in a first direction parallel to the first principal surface, and arranged closer to the terminal region as compared to the gate pad; and
   a second gate runner electrically connected to the gate pad, extending in the first direction, being separated from the first gate runner, and arranged closer to the terminal region as compared to the gate pad,
   wherein, in plan view in a direction perpendicular to the first principal surface, the fourth semiconductor region is provided between the first gate runner and the second gate runner, and includes a fifth semiconductor region contiguous to the first semiconductor region on the first principal surface, and
   wherein the second contact hole includes a fifth contact hole reaching the fifth semiconductor region.
In this case, in the vicinity of the gate pad, the contact resistance between the source pad and the fourth semiconductor region can be further reduced.
[7] In any one of [3] to [5], the silicon carbide semiconductor may be configured to further include:
   a third gate runner electrically connected to the gate pad, extending in a first direction parallel to the first principal surface, and arranged closer to the terminal region as compared to the gate pad,
   wherein, in plan view in a direction perpendicular to the first principal surface, the fourth semiconductor region is provided between the gate pad and the third gate runner, and includes a sixth semiconductor region contiguous to the first semiconductor region on the first principal surface, and
   wherein the second contact hole includes a sixth contact hole reaching the sixth semiconductor region.
In this case, the degree of freedom of arrangement of the gate pad can be increased.
[8] In any one of [3] to [7], the silicon carbide semiconductor may be configured such that the plurality of unit cells extend in a first direction parallel to the first principal surface, and are arrayed in a second direction perpendicular to the first direction,
   wherein the gate pad has, in plan view in a direction perpendicular to the first principal surface, a rectangular planar shape with the first direction as a longitudinal direction,
   wherein the second semiconductor region includes a seventh semiconductor region provided at a position sandwiching the gate pad with the fourth semiconductor region in the second direction, and
   the second contact hole includes a seventh contact hole reaching a seventh semiconductor region.
In this case, the contact resistance between the source pad and the second semiconductor region can be further reduced.
[9] In [8], the silicon carbide semiconductor may be configured such that, in a cross section as viewed in a direction parallel to the first principal surface, a third dimension in a short direction of the third contact hole is equal to a fourth dimension in a short direction of the seventh contact hole.
In this case, a current generated in the first semiconductor region tends to flow evenly toward the third contact hole and the seventh contact hole.
[10] In [8] or [9], the silicon carbide semiconductor may be configured such that a fifth dimension in the first direction of the third contact hole is greater than a sixth dimension in the first direction of the gate pad.
In this case, the contact resistance is more easily reduced.
[11] In any one of [8] to [10], the silicon carbide semiconductor may be configured such that, in plan view, the silicon carbide substrate has a rectangular shape having a first side and a second side parallel to each other, and a third side and a fourth side perpendicular to the first side and the second side,
   and the silicon carbide semiconductor further includes:
   a fourth gate runner extending along the first side;
   a fifth gate runner extending along the second side; and
   a sixth gate runner extending from the gate pad toward the fourth side between the fourth gate runner and the fifth gate runner,
   wherein the fourth gate runner, the fifth gate runner, and the sixth gate runner are electrically connected to the gate pad.
In this case, the gate voltage is more easily applied evenly to the respective unit cells from the fourth, fifth, and sixth gate runners.
[12] In [11], the silicon carbide semiconductor may be configured such that a seventh dimension in the first direction of a part of the seventh contact hole between the fourth gate runner and the sixth gate runner in plan view is greater than or equal to ½ of a distance between the fourth gate runner and the sixth gate runner.
In this case, a dimension in the first direction of the unit cell arranged on an extension line of the seventh contact hole at a portion between the fourth gate runner and the sixth gate runner is less than or equal to ½ of the distance between the fourth gate runner and the sixth gate runner. Therefore, the gate voltage is easily applied to this unit cell at substantially the same level as to the other unit cells.
[13] In or [12], the silicon carbide semiconductor may be configured such that an eighth dimension in the first direction of part of the seventh contact hole between the fifth gate runner and the sixth gate runner in plan view is greater than or equal to ½ of a distance between the fifth gate runner and the sixth gate runner.
In this case, a dimension in the first direction of the unit cell arranged on an extension line of the seventh contact hole at a portion between the fifth gate runner and the sixth gate runner is less than or equal to ½ of the distance between the fifth gate runner and the sixth gate runner. Therefore, the gate voltage is easily applied to this unit cell at substantially the same level as to the other unit cells.
[14] In any one of to [13], the silicon carbide semiconductor may be configured such that, among a plurality of unit cells positioned closer to the fourth side as compared to the seventh semiconductor region, part of the unit cells positioned close to the third side are further away from the sixth gate runner in the second direction as compared to other unit cells.
In this case, the electric field concentration in the vicinity of the sixth gate runner can be alleviated.

### EMBODIMENTS IN THE PRESENT DISCLOSURE

In the following, although embodiments in the present disclosure will be described in detail, the present disclosure is not limited to these embodiments. Note that in the present specification and drawings, elements having substantially the same functional configuration may be denoted by the same reference numerals to omit duplicate descriptions. In the present specification and drawings, the X1-X2 direction, the Y1-Y2 direction, and the Z1-Z2 direction are mutually orthogonal directions. A plane including the X1-X2 direction and the Y1-Y2 direction is denoted as the XY plane, a plane including the Y1-Y2 direction and the Z1-Z2 direction is denoted as the YZ plane, and a plane including the Z1-Z2 direction and the X1-X2 direction is denoted as the ZX plane. Note that for the sake of convenience, the Z1-Z2 direction is defined as the vertical direction, the Z1 side is defined as the upper side, and the Z2 side is defined as the lower side. In addition, plan view refers to a view of an object from the Z1 side, and a plane shape refers to a view of the object from the Z1 side.

### First Embodiment

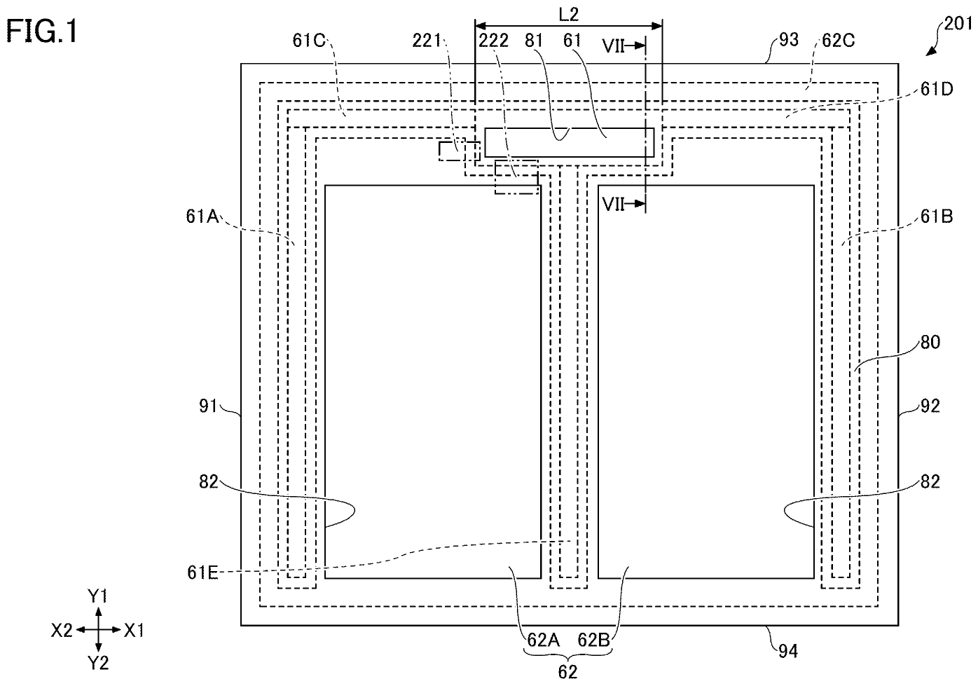

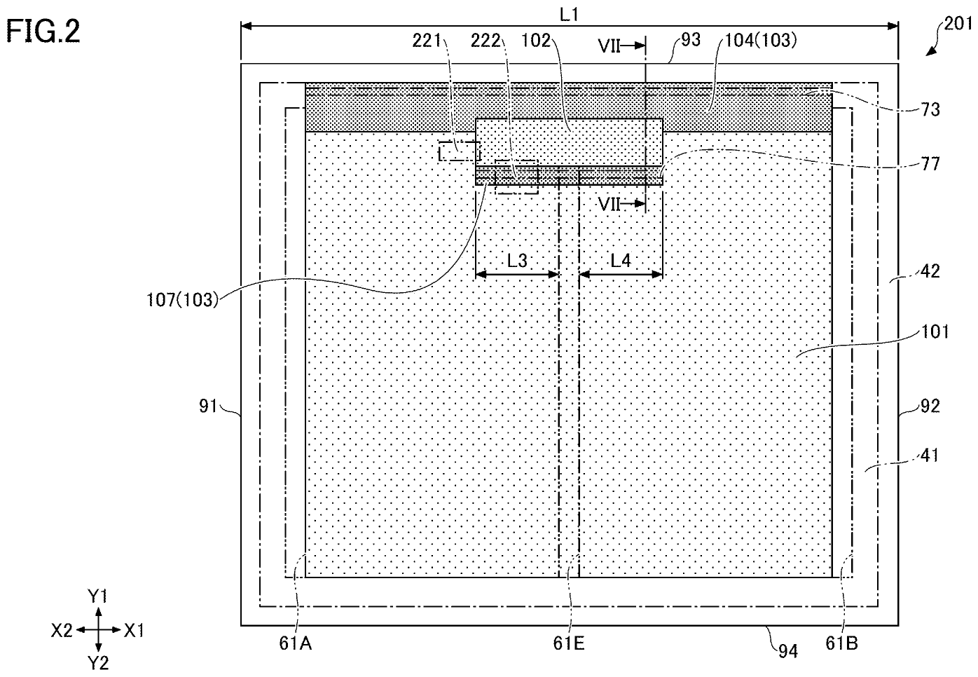

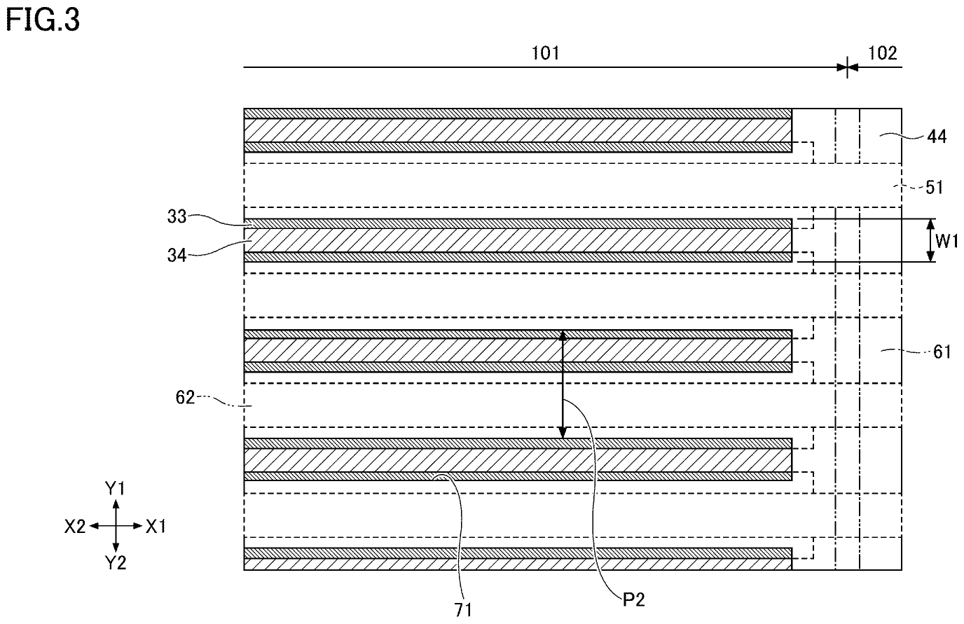

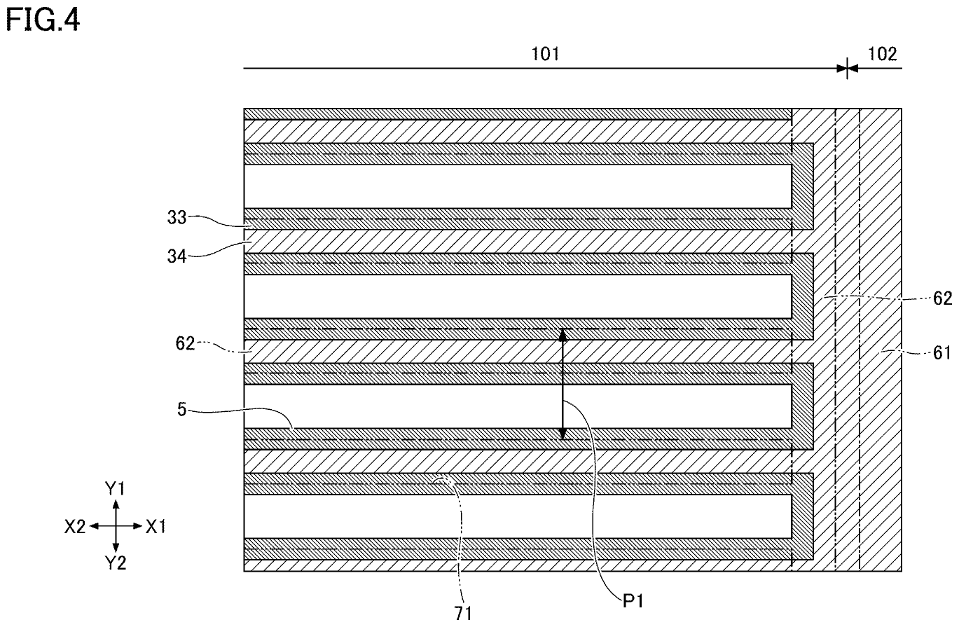

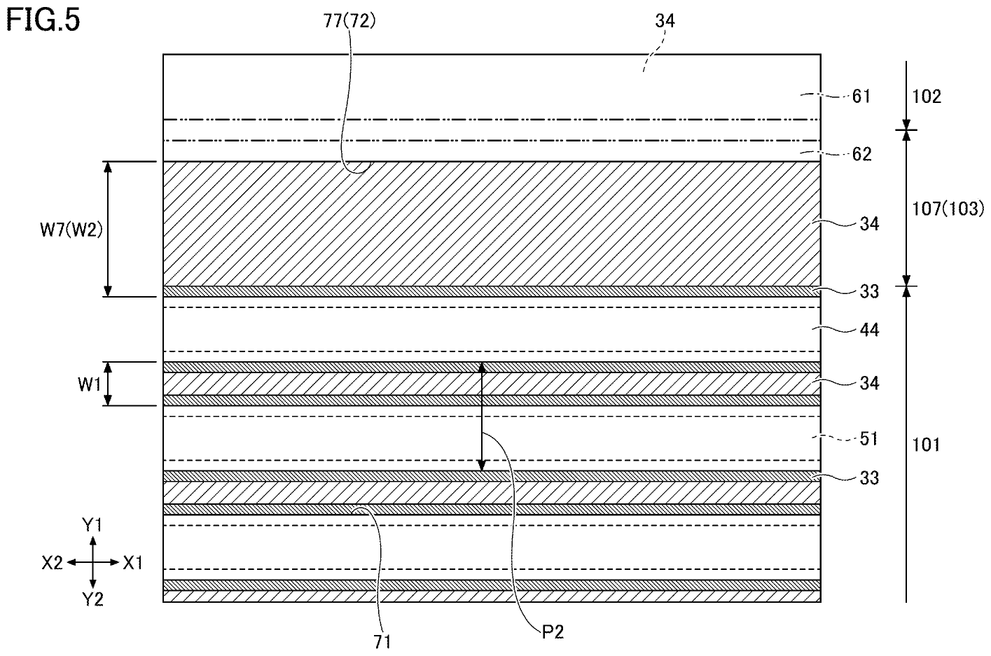

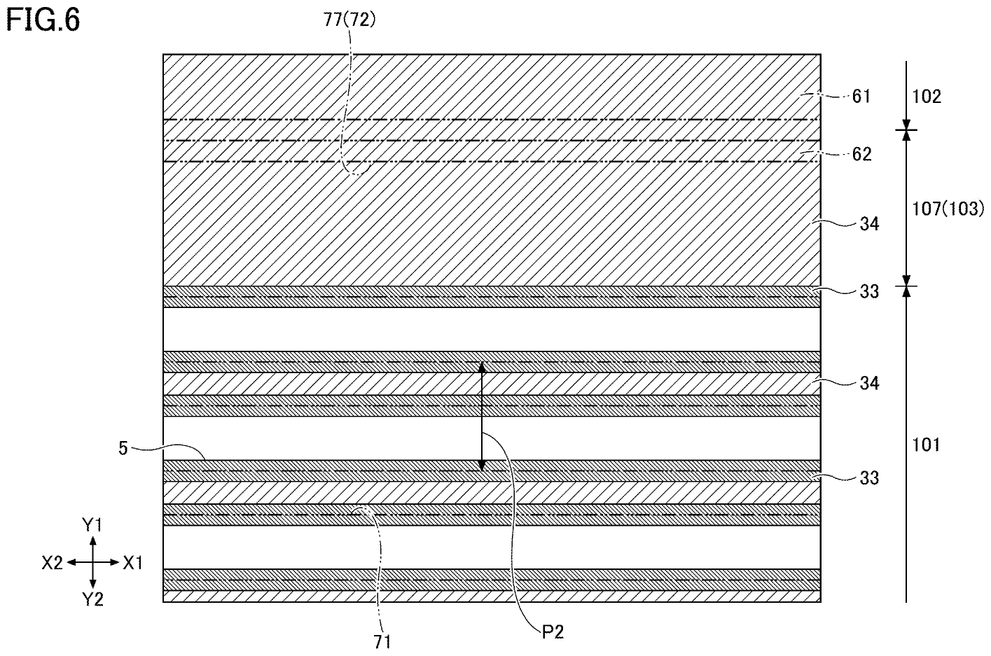

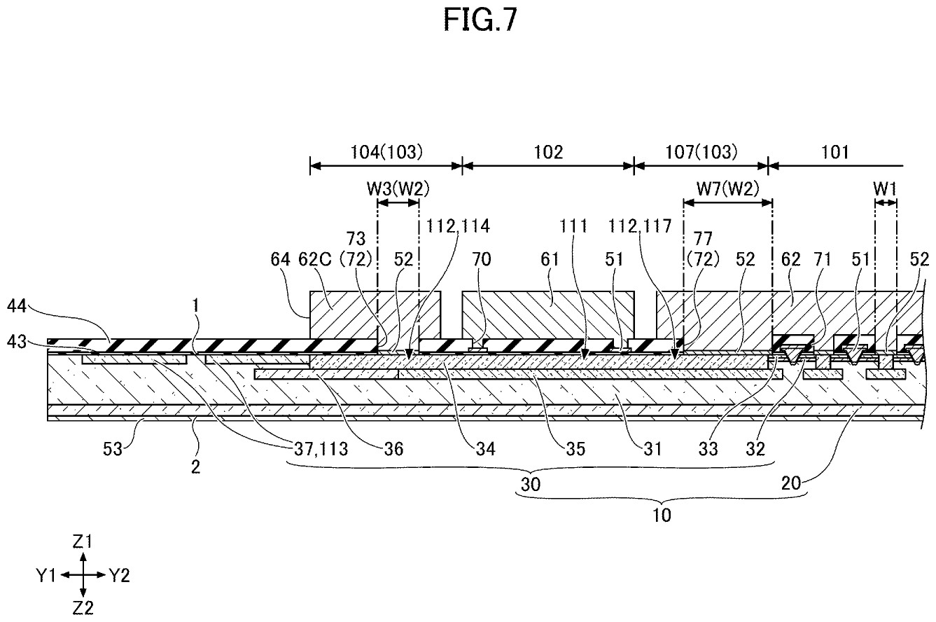

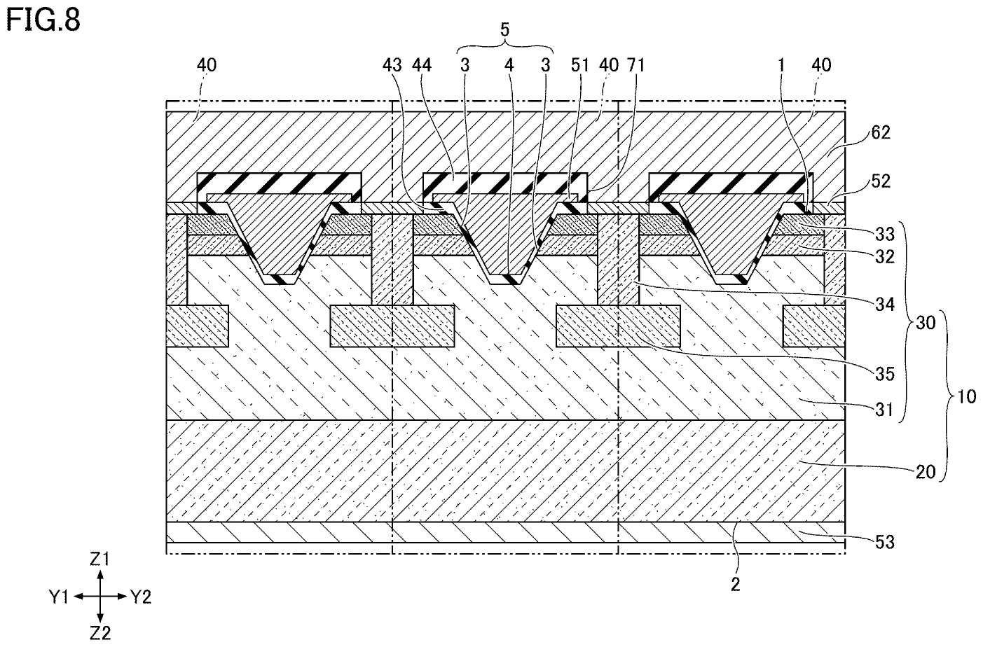

A first embodiment will be described. The first embodiment relates to a what-is-called vertical MOSFET (silicon carbide semiconductor device). FIG. 1 is a top view illustrating a silicon carbide semiconductor device according to the first embodiment. FIG. 2 is a diagram illustrating respective regions in a silicon carbide substrate in the silicon carbide semiconductor device according to the first embodiment. FIG. 3 is a top view illustrating a region 221 in FIGS. 1 and 2 in perspective view of a passivation film, a gate pad, and a source pad. FIG. 4 is a top view illustrating a configuration of a first principal surface of a silicon carbide substrate in the region 221 in FIG. 2. FIG. 5 is a top view illustrating a region 222 in FIG. 2 in perspective view of a passivation film, a gate pad, and a source pad. FIG. 6 is a top view illustrating the region 222 in FIG. 2 in perspective view of a passivation film, a gate pad, and a source pad. FIG. 7 is a cross-sectional view illustrating the silicon carbide semiconductor device according to the first embodiment. FIG. 7 corresponds to a cross-sectional view along a line VII-VII in FIGS. 1 and 2. FIG. 8 is a cross-sectional view illustrating a configuration of a unit cell. In FIGS. 7 and 8, the passivation film is omitted.

As illustrated in FIGS. 1 to 8, a MOSFET 201 according to the first embodiment includes a silicon carbide substrate 10, a gate insulating film 63, a gate electrode 51, an interlayer insulating film 44, a contact electrode 52, a passivation film 80, and a drain electrode 53. The MOSFET 201 further includes a gate pad 61, a source pad 62, a gate runner (gate wiring) 61A, a gate runner 61B, a gate runner 61C, a gate runner 61D, a gate runner 61E, and a source runner (source wiring) 62C. The silicon carbide substrate 10 includes a silicon carbide single-crystal substrate 20, and a silicon carbide epitaxial layer 30 on the silicon carbide single-crystal substrate 20. The silicon carbide substrate 10 includes a first principal surface 1 and a second principal surface 2 opposite to the first principal surface 1. The silicon carbide epitaxial layer 30 forms the first principal surface 1, and the silicon carbide single-crystal substrate 20 forms the second principal surface 2. The silicon carbide single-crystal substrate 20 and the silicon carbide epitaxial layer 30 are formed of, for example, hexagonal silicon carbide of polytype 4H. The silicon carbide single-crystal substrate 20 contains, for example, n-type impurities such as nitrogen (N), and is an n-type (first conductive type).

The first principal surface 1 is a surface on which the {0001} surface or the {0001} surface is inclined by an off angle of 8° or less in the off direction. Favorably, the first principal surface 1 is a surface on which the (000-1) surface or the (000-1) surface is inclined by an off angle of 8° or less in an off direction. The off direction may be, for example, a <11-20> direction or a <1-100> direction. The off angle may be, for example, greater than or equal to 1° or greater than or equal to 2°. The off angle may be less than or equal to 6° or less than or equal to 4°.

In plan view, the silicon carbide substrate 10 has a rectangular shape having a first side 91 and a second side 92 parallel to each other, and a third side 93 and a fourth side 94 perpendicular to the first side 91 and the second side 92. The first side 91 and the second side 92 are parallel to the Y1-Y2 direction, and the third side 93 and the fourth side 94 are parallel to the X1-X2 direction. The first side 91 is on the X2 side of the second side 92, and the second side 92 is on the X1 side of the first side 91. The third side 93 is on the Y1 side of the fourth side 94, and the fourth side 94 is on the Y2 side of the third side 93.

The silicon carbide substrate 10 includes an active region 41 and a terminal region 42 provided around the active region 41 in plan view.

The active region 41 includes a first region 101, a second region 102, and a third region 103. The first region 101 is a region in which multiple unit cells 40 are arranged. The second region 102 is a region overlapping the gate pad 61 in plan view. The unit cells 40 are arrayed in the Y1-Y2 direction where the X1-X2 direction is the longitudinal direction. The dimensions of the respective unit cells 40 in the Y1-Y2 direction are common. Each of the unit cells 40 includes a pair of gate trenches and a gate electrode. The unit cells 40 are arrayed to have regular intervals P1 in the Y1-Y2 direction. The X1-X2 direction is an example of a first direction, and the Y1-Y2 direction is an example of a second direction.

The silicon carbide epitaxial layer 30 mainly includes a drift region 31, a body region 32, a source region 33, a contact region 34, an embedded region 35, an embedded junction termination extension (JTE) region 36, and a surface JTE region 37. The drift region 31 is provided across the active region 41 and the terminal region 42. The body region 32, the source region 33, the contact region 34, and the embedded region 35 are provided in the active region 41. The embedded JTE region 36 and the surface JTE region 37 are provided in the terminal region 42. Part of the contact region 34 and the embedded region 35 may also be provided in the terminal region 42.

The drift region 31 is provided on the silicon carbide single-crystal substrate 20. The drift region 31 is positioned closer to the first principal surface 1 as compared to the silicon carbide single-crystal substrate 20. The drift region 31 may be contiguous to the silicon carbide single-crystal substrate 20. The drift region 31 contains, for example, n-type impurities such as nitrogen or phosphorus (P), and has an n-type conductive type.

The body region 32 is provided on the drift region 31. The body region 32 contains, for example, p-type impurities such as aluminum (Al), and has a p-type conductive type (second conductive type). The body region 32 is positioned closer to the first principal surface 1 as compared to the drift region 31. The drift region 31 is positioned closer to the second principal surface 2 as compared to the body region 32. The body region 32 is adjacent to the drift region 31.

The source region 33 is provided on the body region 32. The source region 33 is separated from the drift region 31 by the body region 32. The source region 33 contains, for example, n-type impurities such as nitrogen or phosphorus, and has an n-type conductive type. The source region 33 is positioned closer to the first principal surface 1 as compared to the body region 32. The body region 32 is positioned closer to the second principal surface 2 as compared to the source region 33. The source region 33 is adjacent to the body region 32. The source region 33 forms part of the first principal surface 1. The source region 33 is covered with a gate insulating film 43. The source region 33 is directly in contact with the gate insulating film 43.

The contact region 34 contains, for example, p-type impurities such as aluminum, and has a p-type conductive type. The concentration of the p-type impurities in the contact region 34 is higher than, for example, the concentration of the p-type impurities in the body region 32. The contact region 34 penetrates the source region 33 and the body region 32. The contact region 34 is in contact with the body region 32. The contact region 34 forms part of the first principal surface 1.

As illustrated in FIG. 8, in the first region 101, a gate trench 5 demarcated by a side surface 3 and a bottom surface 4 is provided on the first principal surface 1. The side surface 3 penetrates the source region 33 and the body region 32, to reach the drift region 31. The bottom surface 4 is contiguous to the side surface 3. The source region 33, the body region 32, and the drift region 31 are in contact with the side surface 3. The bottom surface 4 is positioned in the drift region 31. The bottom surface 4 is, for example, a plane parallel to the second principal surface 2. An angle θ1 of the side surface 3 with respect to a plane including the bottom surface 4 is, for example, 45° to 65°. The angle θ1 may be, for example, greater than or equal to 50°. The angle θ1 may be, for example, less than or equal to 60°. The side surface 3 favorably includes a {0-33-8} surface. The {0-33-8} surface is a crystal surface that provides excellent mobility.

In plan view, the gate trench 5 extends in the X1-X2 direction parallel to the first principal surface 1. In addition, in plan view, multiple gate trenches 5 are provided at regular intervals in the Y1-Y2 direction. The gate trenches 5 are not provided in the second region 102 and the third region 103.

The embedded region 35 contains, for example, p-type impurities such as aluminum, and has a p-type conductive type. The embedded region 35 is positioned closer to the second principal surface 2 as compared to the contact region 34. The contact region 34 is positioned closer to the first principal surface 1 as compared to the embedded region 35. The embedded region 35 is in contact with the contact region 34. The embedded region 35 is formed at a position deeper than the gate trench 5. The upper end surface of the embedded region 35 is positioned closer to the second principal surface 2 as compared to the bottom surface 4 of the gate trench 5.

The embedded JTE region 36 is in contact with the embedded region 35 in a direction parallel to the first principal surface 1. The embedded JTE region 36 is formed to have an annular shape in plan view. The embedded JTE region 36 contains, for example, p-type impurities such as aluminum, and has a p-type conductive type. The embedded JTE region 36 is separated from the first principal surface 1 and the second principal surface 2. The upper end surface of the embedded JTE region 36 is in contact with the lower end surface of the contact region 34.

The surface JTE region 37 is in contact with the contact region 34 in a direction parallel to the first principal surface 1. The surface JTE region 37 is formed to have an annular shape in plan view. The surface JTE region 37 contains, for example, p-type impurities such as aluminum, and has a p-type conductive type. The surface JTE region 37 is provided above the embedded JTE region 36. The surface JTE region 37 is separated from the embedded JTE region 36. The surface JTE region 37 is positioned closer to the first principal surface 1 as compared to the embedded JTE region 36. The embedded JTE region 36 is positioned closer to the second principal surface 2 as compared to the surface JTE region 37. The surface JTE region 37 forms the first principal surface 1. Part of the drift region 31 is present between the surface JTE region 37 and the embedded JTE region 36. For example, the concentration of the p-type impurities in the surface JTE region 37 is lower than the concentration of the p-type impurities in the contact region 34. The surface JTE region 37 is an example of the third semiconductor region 113.

The gate insulating film 43 is, for example, an oxide film. The gate insulating film 43 is, for example, formed of a material containing silicon dioxide. The gate insulating film 43 is in contact with the side surface 3 and the bottom surface 4. The gate insulating film 43 is in contact with the drift region 31 on the bottom surface 4. The gate insulating film 43 is in contact with each of the source region 33, the body region 32, and the drift region 31 on the side surface 3. The gate insulating film 43 may be in contact with the source region 33, the contact region 34, and the surface JTE region 37 on the first principal surface 1.

The gate electrode 51 is provided on the gate insulating film 43. The gate electrode 51 is formed of, for example, polysilicon (poly-Si) containing conductive impurities. Part of the gate electrode 51 is arranged inside the gate trench 5. Part of the gate electrode 51 is arranged above the first principal surface 1.

The interlayer insulating film 44 is provided in contact with the gate electrode 51 and the gate insulating film 43. The interlayer insulating film 44 is, for example, an oxide film. The interlayer insulating film 44 is, for example, formed of a material containing silicon dioxide. The interlayer insulating film 44 electrically insulates the gate electrode 51, the contact electrode 52, and the source pad 62.

Contact holes 70 for the gate are formed in the interlayer insulating film 44. Through the contact hole 70, the gate electrode 51 is exposed from the interlayer insulating film 44.

The gate pad 61 is provided on the interlayer insulating film 44, and is in contact with the gate electrode 51 in the contact hole 70. The gate pad 61 is formed of a material containing, for example, aluminum.

Contact holes 71 for the source are formed in the interlayer insulating film 44 and the gate insulating film 43. Through the contact hole 71, the source region 33 and the contact region 34 in the first region 101 are exposed from the interlayer insulating film 44 and the gate insulating film 43. The contact hole 71 is an example of a first contact hole.

Contact holes 72 are formed in the interlayer insulating film 44 and the gate insulating film 43. Through the contact hole 72, the contact region 34 in the third region 103 are exposed from the interlayer insulating film 44 and the gate insulating film 43. Part of the source region 33 may be exposed through the contact hole 72. In a cross section as viewed in a direction parallel to the first principal surface 1, a dimension W2 in the short direction of the contact hole 72 is greater than a dimension W1 in the short direction of the contact hole 71. The dimension W1 is a dimension of the contact hole 71 in the Y1-Y2 direction, and the dimension W2 is a dimension of the contact hole 72 in the Y1-Y2 direction. The contact hole 72 is an example of a second contact hole. The dimension W1 is an example of a first dimension, and the dimension W2 is an example of a second dimension.

The contact electrode 52 is in contact with the source region 33 and the contact region 34 in the contact hole 71. The contact electrode 52 is formed of a material containing, for example, nickel silicide (NiSi). The contact electrode 52 may be formed of a material containing titanium, aluminum, and silicon. The contact electrode 52 has an ohmic contact with the source region 33 and the contact region 34.

The source pad 62 is provided on the interlayer insulating film 44, and is in contact with the contact electrode 52 in the contact hole 71. The source pad 62 is formed of a material containing, for example, aluminum. The source pad 62 may include a barrier metal film (not illustrated) covering the surface of the interlayer insulating film 44. As illustrated in FIG. 1, the source pad 62 may include source pads 62A and 62B. For example, the source pad 62A is positioned on the X2 side of the silicon carbide substrate 10 relative to its center in the X1-X2 direction, and the source pad 62B is positioned on the X1 side of the silicon carbide substrate 10 relative to its center in the X1-X2 direction.

The gate pad 61 is positioned on the Y1 side of the source pad 62, and the planar shape of the gate pad 61 is rectangular. For example, the dimension of the gate pad 61 in the X1-X2 direction is greater than that in the Y1-Y2 direction. The source pad 62 is positioned on the Y2 side of the gate pad 61, and the planar shape of the source pad 62 is rectangular. The distance from the first side 91 of the gate pad 61 is substantially the same as the distance from the second side 92. The distance from the third side 93 of the gate pad 61 is smaller than the distance from the fourth side 94. The distance from the first side 91 of the source pad 62 is substantially the same as the distance from the second side 92. The distance from the third side 93 of the source pad 62 is greater than the distance from the fourth side 94. The dimension of the gate pad 61 in the X1-X2 direction may be smaller than the dimension of the source pad 62 in the X1-X2 direction, and the dimension of the gate pad 61 in the Y1-Y2 direction may be smaller than the dimension of the source pad 62 in the Y1-Y2 direction. The source pad 62 is arranged to include a centerline that divides the silicon carbide substrate 10 into two parts in the Y1-Y2 direction in plan view.

The gate runner 61A extends along the first side 91 in the Y1-Y2 direction. The gate runner 61B extends along the second side 92 in the Y1-Y2 direction. The gate runners 61C and 61D are connected to the gate pad 61. The gate runners 61C and 61D extend along the third side 93 in the X1-X2 direction. The gate runner 61C is positioned on the X2 side of the gate pad 61, and the gate runner 61D is positioned on the X1 side of the gate pad 61. An end of the gate runner 61A on the Y1 side is connected to an end of the gate runner 61C on the X2 side. An end of the gate runner 61B on the Y1 side is connected to an end of the gate runner 61D on the X1 side. The gate runner 61A is positioned on the X2 side of the source pad 62A, and the gate runner 61B is positioned on the X1 side of the source pad 62B. In this way, the gate pad 61 is contiguous to the gate runners 61C and 61D, the gate runner 61A is contiguous to the gate runner 61C, and the gate runner 61B is contiguous to the gate runner 61D. The gate runners 61A and 61B are separated from the gate pad 61 in the X1-X2 direction. The gate runner 61E is connected to the gate pad 61, and extends in the Y1-Y2 direction between the source pad 62A and the source pad 62B. The gate runners 61A, 61B, 61C, 61D, and 61E are formed of substantially the same material as the gate pad 61. The gate runner 61C is an example of a first gate runner, and the gate runner 61D is an example of a second gate runner. The gate runner 61A is an example of a fourth gate runner, the gate runner 61B is an example of a fifth gate runner, and the gate runner 61E is an example of a sixth gate runner.

The source runner 62C is provided to have an annular shape in plan view, outside the source pad 62, the gate runners 61A, 61B, 61C, and 61D. The source runner 62C is connected to the source pad 62 and is contiguous to the source pad 62. The source runner 62C is formed of substantially the same material as the source pad 62. A contact hole for the source runner 62C is formed to have an annular shape in the interlayer insulating film 44 and the gate insulating film 43, and the source runner 62C is electrically connected to the contact region 34 through the annular contact hole. It is favorable that, in a cross section as viewed in a direction parallel to the first principal surface 1, the side surface 64 of the source runner 62C on a side away from the gate pad 61 is positioned on a boundary line between the contact region 34 and the surface JTE region 37, or closer to the gate pad 61 as compared to this boundary line. This is because the electric field concentration on the interlayer insulating film 44 below the source runner 62C can be easily alleviated.

The passivation film 80 covers the gate pad 61, the source pad 62, and the interlayer insulating film 44. The passivation film 80 is in contact with the gate pad 61, the source pad 62, and the interlayer insulating film 44. The passivation film 80 also covers the gate runners 61A, 61B, 61C, 61D, and 61E, and the source runner 62C. The passivation film 80 is also in contact with the gate runners 61A, 61B, 61C, 61D, and 61E, and the source runner 62C. The passivation film 80 is formed of a material containing, for example, silicon nitride or polyimide. An opening 81 for exposing part of the upper surface of the gate pad 61 and an opening 82 for exposing part of the upper surface of the source pad 62 are formed in the passivation film 80.

The drain electrode 53 is in contact with the second principal surface 2. The drain electrode 53 is in contact with the silicon carbide single-crystal substrate 20 on the second principal surface 2. The drain electrode 53 is electrically connected to the drift region 31. The drain electrode 53 is formed of a material containing, for example, nickel silicide. The drain electrode 53 may be formed of a material containing titanium, aluminum, and silicon. The drain electrode 53 has an ohmic contact with the silicon carbide single-crystal substrate 20. A buffer layer containing n-type impurities such as nitrogen and having an n-type conductive type may be provided between the silicon carbide single-crystal substrate 20 and the drift region 31.

The second region 102 is positioned on the Z2 side of the gate pad 61. The third region 103 is contiguous to the second region 102. The third region 103 includes a fourth region 104 and a seventh region 107. The fourth region 104 is positioned on the Z2 side of the gate runner 61C, the Z2 side of the gate runner 61D, and in plan view, on the Y1 side of the gate pad 61, the gate runner 61C, and the gate runner 61D. The seventh region 107 is positioned on the Y2 side of the gate pad 61 in plan view. The first region 101 is positioned on the Y2 side of the seventh region 107, and the Y2 side of the gate runners 61C and 61D in plan view. The first region 101 is provided in the X1-X2 direction from the vicinity of the gate runner 61A toward the vicinity of the gate runner 61B.

As described above, the gate trench 5 is provided in the first region 101, but not in the second region 102 and the third region 103. The source region 33 is also provided in the first region 101, but not in the second region 102 and the third region 103. Therefore, in the second region 102 and the third region 103, the first principal surface 1 is formed by the contact region 34. The contact region 34 in the first region 101, the contact region 34 in the second region 102, and the contact region 34 in the third region 103 are contiguous to each other on the first principal surface 1. In the present embodiment, the source region 33 is provided between the gate trenches 5 adjacent in the Y1-Y2 direction. Each of the unit cells 40 includes a pair of gate trenches 5 and a gate electrode 51, and multiple unit cells 40 are arranged in the first region 101 to have regular intervals P1 in the Y1-Y2 direction. The contact region 34 in the second region 102 is an example of the first semiconductor region 111, and the contact region 34 in the third region 103 is an example of the second semiconductor region 112. The contact region 34 in the fourth region 104 is an example of the fourth semiconductor region 114, and the contact region 34 in the seventh region 107 is an example of the seventh semiconductor region 117.

On the Z1 side of the first region 101, the source contact holes 71 formed in the interlayer insulating film 44 are arranged to have regular intervals P2 equal to the intervals P1 in the Y1-Y2 direction.

On the Z1 side of the second region 102, the gate contact holes 70 are formed in the interlayer insulating film 44, but the contact holes 71 and 72 are not formed. The contact holes 70 for the gate are also formed in part of the interlayer insulating film 44 between the gate runners 61A, 61B, 61C, 61D, and 61E, and the gate electrode 51.

On the Z1 side of the third region 103, the contact hole 72 includes a contact hole 73 reaching the contact region 34 in the fourth region 104 and a contact hole 77 reaching the contact region 34 in the seventh region 107. In a cross section as viewed in a direction parallel to the first principal surface 1, a dimension W3 in the short direction of the contact hole 73 and a dimension W7 in the short direction of the contact hole 77 are greater than a dimension W1 in the short direction of the contact hole 71. The dimension W3 is a dimension of the contact hole 73 in the Y1-Y2 direction, and the dimension W7 is a dimension of the contact hole 77 in the Y1-Y2 direction. The dimension W3 may be equal to the dimension W7. The contact hole 73 is an example of a third contact hole, and the contact hole 77 is an example of a seventh contact hole. The dimension W3 is an example of a third dimension, and the dimension W7 is an example of a fourth dimension. The contact hole 73 is part of the contact hole for the source runner 62C.

In the contact hole 73 and the contact hole 77, the contact electrode 52 is in contact with the contact region 34. The contact electrode 52 has an ohmic contact with the contact region 34. The source pad 62 is in contact with the contact electrode 52 also in the contact hole 77. The source runner 62C is in contact with the contact electrode 52 in the contact hole 73.

In the first embodiment, the third region 103 contiguous to the second region 102 is provided, and the contact region 34 is arranged contiguously in the second region 102 and the third region 103. In addition, in a cross section as viewed in a direction parallel to the first principal surface 1, the dimension W2 in the short direction of the contact hole 72 is greater than the dimension W1 in the short direction of the contact hole 71. Therefore, the contact resistance between the source pad 62 and the contact region 34 can be reduced, and even if a surge occurs, electric field concentration on the interlayer insulating film 44 in the second region 102 can be reduced.

In addition, as the contact region 34 is in contact with the surface JTE region 37, even in the case where a great voltage is applied between the drain electrode 53 and the source runner 62C, the electric field concentration on the interlayer insulating film 44 below the source runner 62C can be reduced.

Further, in the present embodiment, the third region 103 includes the fourth region 104 and the seventh region 107. Although the third region 103 may include only one of the fourth region 104 or the seventh region 107, including both the fourth region 104 and the seventh region 107 can further reduce the contact resistance between the source pad 62 and the contact region 34. In addition, in the case where the dimension W3 in the short direction of the contact hole 73 is equal to the dimension W7 in the short direction of the contact hole 77, a current generated at the contact region 34 in the second region 102 tends to flow evenly toward the contact hole 73 and the contact hole 77.

In addition, as the gate runners 61A, 61B, and 61E extending in the Y1-Y2 direction are provided, the gate voltage is easily applied evenly to each of the unit cells 40 from the gate runners 61A, 61B, and 61E.

Further, as the contact region 34 in the first region 101 and the contact region 34 in the third region 103 are contiguous to each other, these regions are easily controlled to the same potential.

Note that it is favorable that a dimension L1 in the X1-X2 direction of the contact hole 73 is greater than a dimension L2 in the X1-X2 direction of the gate pad 61. This is because it is easier to reduce the contact resistance in the fourth region 104. The dimension L1 is an example of a fifth dimension, and the dimension L2 is an example of a sixth dimension.

In addition, it is favorable that a dimension L3 in the X1-X2 direction of part of the contact hole 77 between the gate runners 61A and 61E in plan view is greater than or equal to ½ of the distance between the gate runners 61A and 61E. In this case, a dimension in the X1-X2 direction of the unit cell 40 arranged on an extension line of the contact hole 77 at a portion between the gate runner 61A and the gate runner 61E is less than or equal to ½ of the distance between the gate runner 61A and the gate runner 61E. Therefore, the gate voltage is easily applied to this unit cell 40 at substantially the same level as to the other unit cells 40. The dimension L3 is an example of a seventh dimension.

Similarly, it is favorable that a dimension L4 in the X1-X2 direction of part of the contact hole 77 between the gate runners 61B and 61E in plan view is greater than or equal to ½ of the distance between the gate runners 61B and 61E. In this case, a dimension in the X1-X2 direction of the unit cell 40 arranged on an extension line of the contact hole 77 at a portion between the gate runner 61B and the gate runner 61E is less than or equal to ½ of the distance between the gate runner 61B and the gate runner 61E. Therefore, the gate voltage is easily applied to this unit cell 40 at substantially the same level as to the other unit cells 40. The dimension L4 is an example of an eighth dimension.

### Second Embodiment

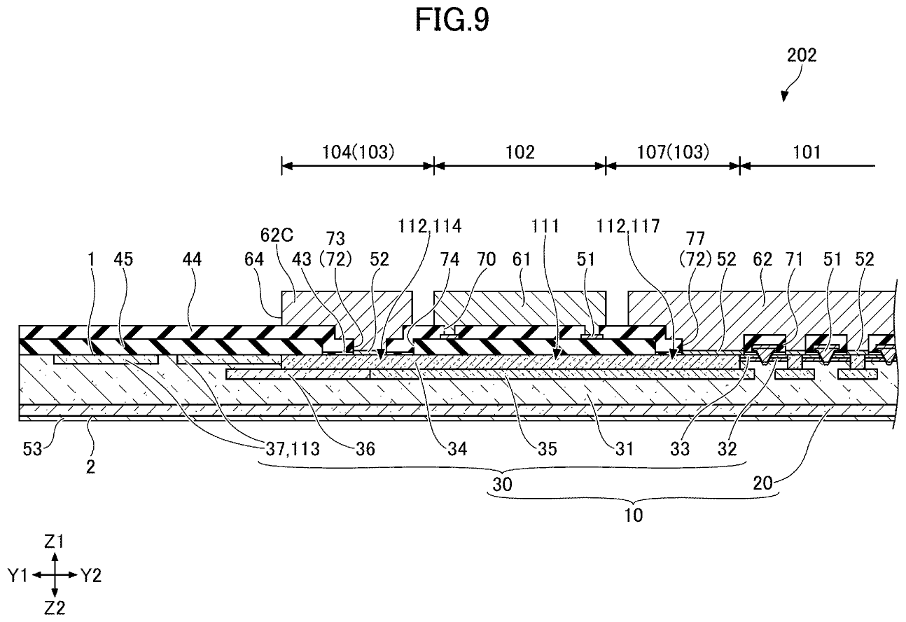

Next, a second embodiment will be described. The second embodiment differs from the first embodiment primarily in having a field insulating film. FIG. 9 is a cross-sectional view illustrating a silicon carbide semiconductor device according to a second embodiment. As in FIG. 7, FIG. 9 corresponds to a cross-sectional view along a line VII-VII in FIGS. 1 and 2. In FIG. 9, the passivation film is omitted.

As illustrated in FIG. 9, a MOSFET 202 according to the second embodiment includes a field insulating film 45. The field insulating film 45 is provided on the second region 102, the fourth region 104, and the terminal region 42. In the field insulating film 45, a contact hole 74 reaching the contact region 34 in the fourth region 104 is formed on the Y1 side relative the gate pad 61 and the gate runners 61C and 61D in plan view. The interlayer insulating film 44 is provided on the field insulating film 45 above the second region 102, the fourth region 104, and the terminal region 42. The interlayer insulating film 44 is also provided inside the contact hole 74. Inside the contact hole 74, the gate insulating film 43 is provided between the interlayer insulating film 44 and the contact region 34. The contact hole 73 is smaller than the contact hole 74, and is positioned inside the contact hole 74. Above the second region 102, the gate electrode 51 is provided on the field insulating film 45. The contact hole 74 is an example of a fourth contact hole.

The other elements are substantially the same as in the first embodiment.

According to the second embodiment, as the field insulating film 45 is provided, the electric field concentration in the interlayer insulating film 44 can be more alleviated.

### Third Embodiment

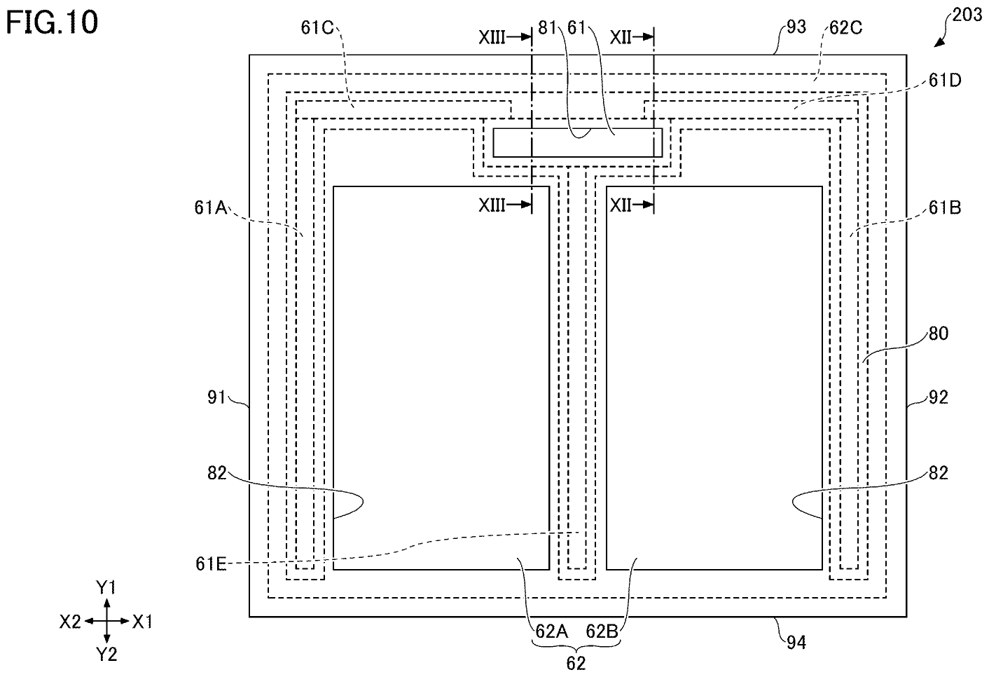

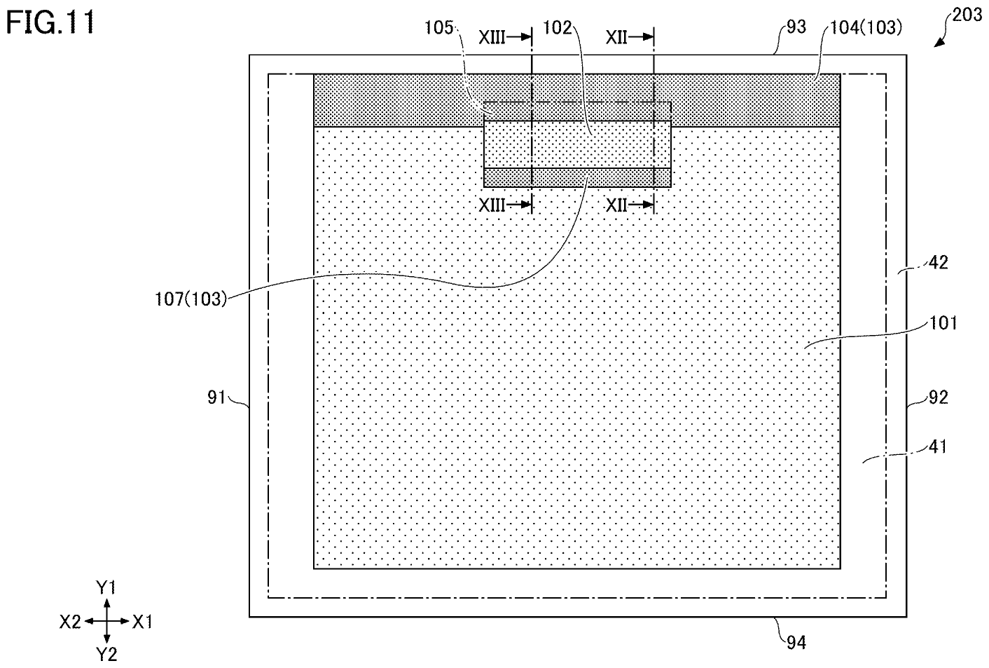

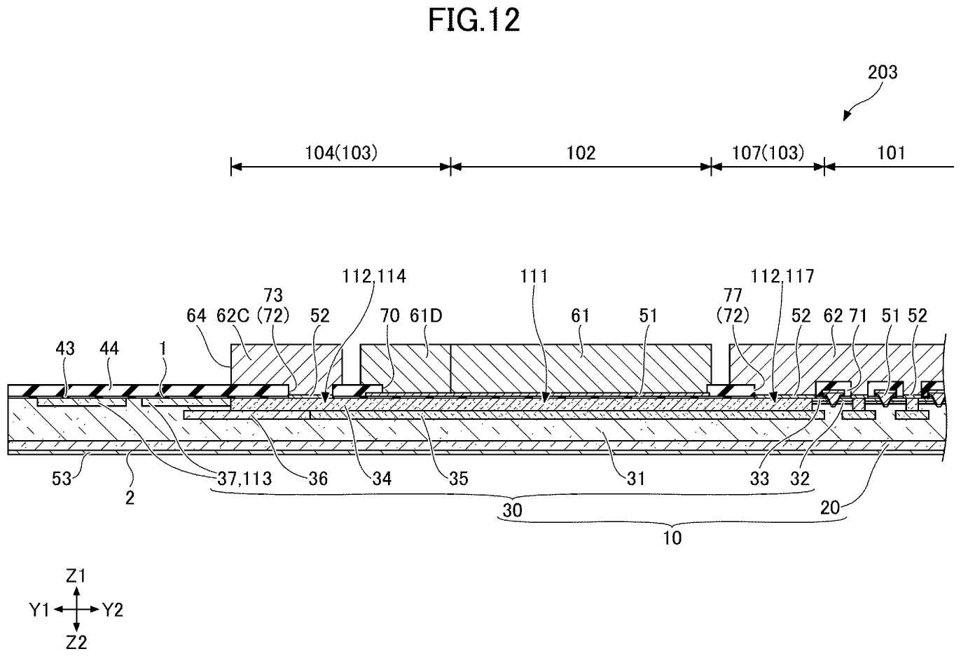

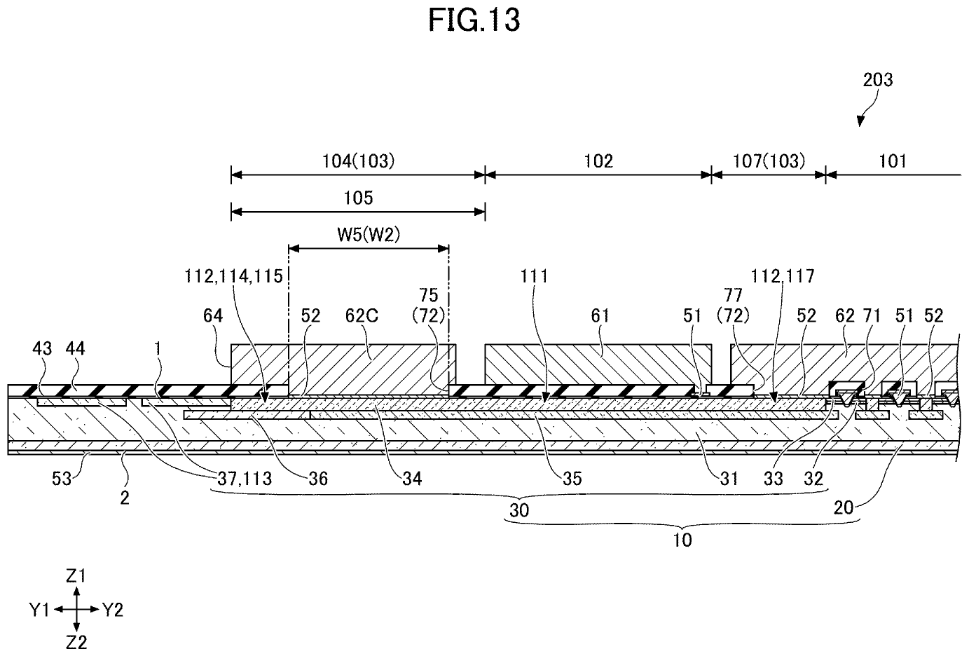

Next, a third embodiment will be described. The third embodiment differs from the first embodiment mainly in the arrangement of the gate pad 61. FIG. 10 is a top view illustrating a silicon carbide semiconductor device according to the third embodiment. FIG. 11 is a diagram illustrating respective regions in a silicon carbide substrate in the silicon carbide semiconductor device according to the third embodiment. FIGS. 12 and 13 are cross-sectional views illustrating the silicon carbide semiconductor device according to the third embodiment. FIG. 12 corresponds to a cross-sectional view along a line XII-XII in FIGS. 10 and 11. FIG. 13 corresponds to a cross-sectional view along a line XIII-XIII in FIGS. 10 and 11. In FIGS. 12 and 13, the passivation film is omitted.

As illustrated in FIGS. 10 to 13, in a MOSFET 203 according to the third embodiment, although the gate pad 61 is in contact with the gate runners 61C and 61D, the gate pad 61 is arranged on the Y2 side relative to the gate runners 61C and 61D. Therefore, there is no gate pad 61 between the gate runners 61C and 61D. The gate runners 61C and 61D are separated from each other.

The fourth region 104 includes a fifth region 105 provided between the gate runners 61C and 61D in plan view. The fifth region 105 is contiguous to the second region 102 on the first principal surface 1. In other words, the contact region 34 in the fourth region 104 includes the contact region 34 between the gate runner 61C and the gate runner 61D in plan view. The contact region 34 between the gate runner 61C and the gate runner 61D in plan view is contiguous to the contact region 34 in the second region 102 on the first principal surface 1. The contact region 34 in the fifth region 105 is an example of a fifth semiconductor region 115.

The contact hole 72 includes a contact hole 75 reaching the contact region 34 between the gate runner 61C and the gate runner 61D in plan view. In plan view, the contact hole 75 is positioned on the Y1 side of the gate pad 61 and positioned between the gate runner 61C and the gate runner 61D. In a cross section as viewed in a direction parallel to the first principal surface 1, a dimension W5 in the short direction of the contact hole 75 is greater than the dimension W1 in the short direction of the contact hole 71. The contact hole 75 may be part of the contact hole 73. The dimension W5 may be greater than the dimension W3 of the other part of the contact hole 73. The contact hole 75 is an example of a fifth contact hole.

In the contact hole 75, the contact electrode 52 is in contact with the contact region 34. The contact electrode 52 has an ohmic contact with the contact region 34. The source pad 62 is also in contact with the contact electrode 52 in the contact hole 75.

The other elements are substantially the same as in the first embodiment.

The third embodiment also brings substantially the same effects as in the first embodiment. In addition, in the vicinity of the gate pad 61, the contact resistance between the source runner 62C connected to the source pad 62 and the contact region 34 in the fourth region 104 can be further reduced.

### Fourth Embodiment

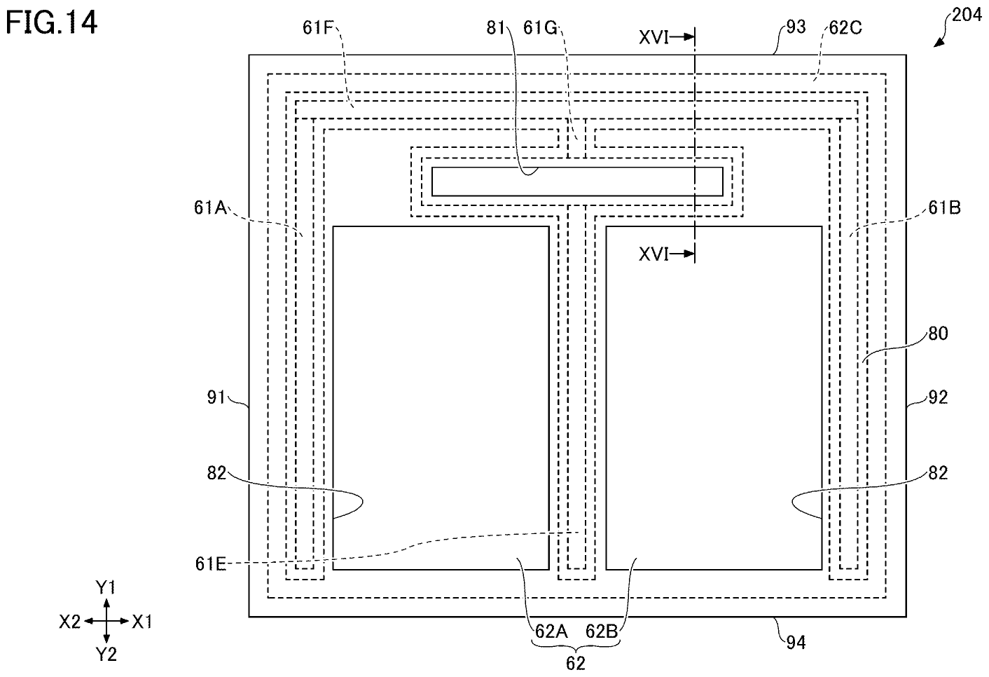

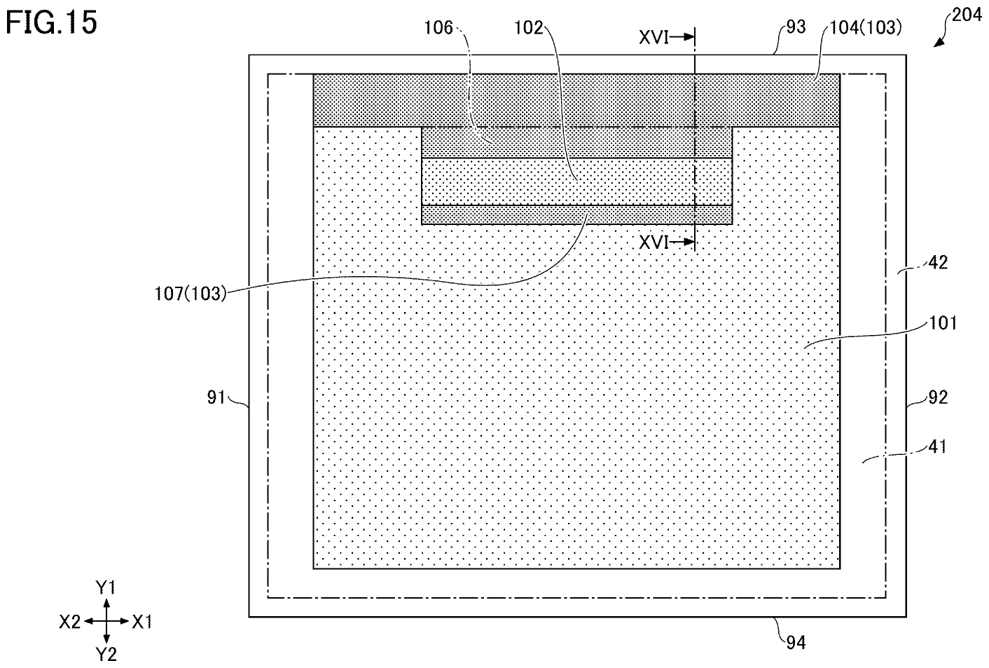

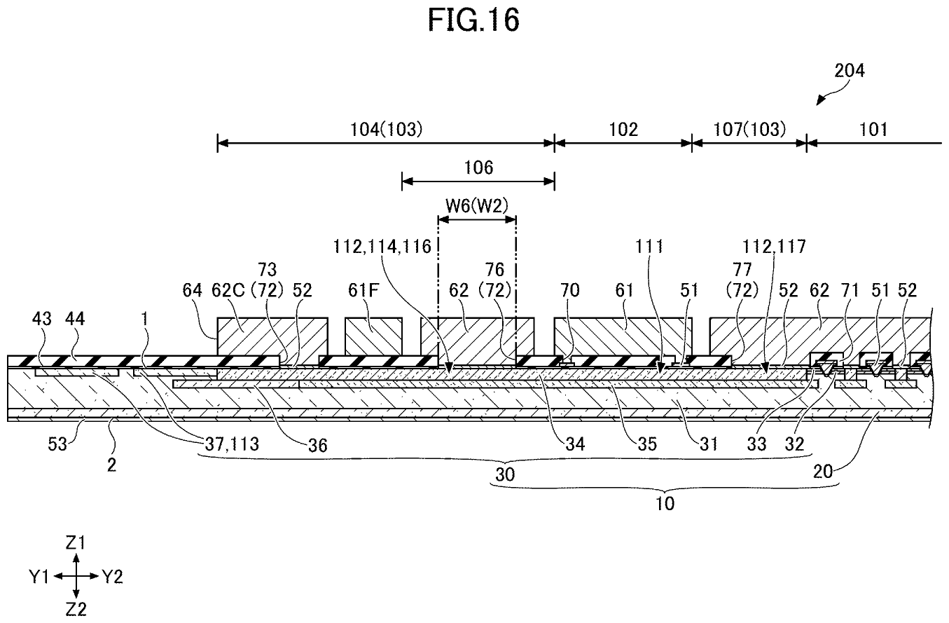

Next, a fourth embodiment will be described. The fourth embodiment differs from the first embodiment mainly in the arrangement of the gate pad 61. FIG. 14 is a top view illustrating a silicon carbide semiconductor device according to the fourth embodiment. FIG. 15 is a diagram illustrating respective regions in a silicon carbide substrate in the silicon carbide semiconductor device according to the fourth embodiment. FIG. 16 is a cross-sectional view illustrating a silicon carbide semiconductor device according to a fourth embodiment. FIG. 16 corresponds to a cross-sectional view along a line XVI-XVI in FIGS. 14 and 15. In FIG. 16, the passivation film is omitted.

As illustrated in FIGS. 14 to 16, a MOSFET 204 according to the fourth embodiment includes a gate runner 61F in place of the gate runners 61C and 61D. The gate runner 61F extends along the third side 93 in the X1-X2 direction. An end of the gate runner 61A on the Y1 side is connected to an end of the gate runner 61F on the X2 side. An end of the gate runner 61B on the Y1 side is connected to an end of the gate runner 61F on the X1 side. The gate pad 61 is separated from the gate runner 61F in the Y1-Y2 direction. The MOSFET 204 further includes a gate runner 61G. The gate runner 61G extends in the Y1-Y2 direction to connect the gate runner 61F and the gate pad 61. The gate runners 61F and 61G are formed of substantially the same material as the gate pad 61. The gate runner 61F is an example of a third gate runner,

The fourth region 104 includes a sixth region 106 provided between the gate pad 61 and the gate runner 61F in plan view. The sixth region 106 is contiguous to the second region 102 on the first principal surface 1. In other words, the contact region 34 in the fourth region 104 includes a portion between the gate pad 61 and the gate runner 61F in plan view. The contact region 34 between the gate pad 61 and the gate runner 61F in plan view is contiguous to the contact region 34 in the second region 102 on the first principal surface 1. The contact region 34 in the sixth region 106 is an example of a sixth semiconductor region 116.

The contact hole 72 includes a contact hole 76 reaching the contact region 34 between the gate pad 61 and the gate runner 61F in plan view. In plan view, the contact hole 76 is positioned on the Y1 side of the gate pad 61 and positioned on the Y2 side of the gate runner 61F. In a cross section as viewed in a direction parallel to the first principal surface 1, a dimension W6 in the short direction of the contact hole 76 is greater than the dimension W1 in the short direction of the contact hole 71. The contact hole 76 is an example of a sixth contact hole.

In the contact hole 76, the contact electrode 52 is in contact with the contact region 34. The contact electrode 52 has an ohmic contact with the contact region 34. The source pad 62 is also in contact with the contact electrode 52 in the contact hole 76.

The other elements are substantially the same as in the first embodiment.

The fourth embodiment also brings substantially the same effects as in the first embodiment. In addition, according to the fourth embodiment, the degree of freedom of arrangement of the gate pad 61 can be increased.

### Fifth Embodiment

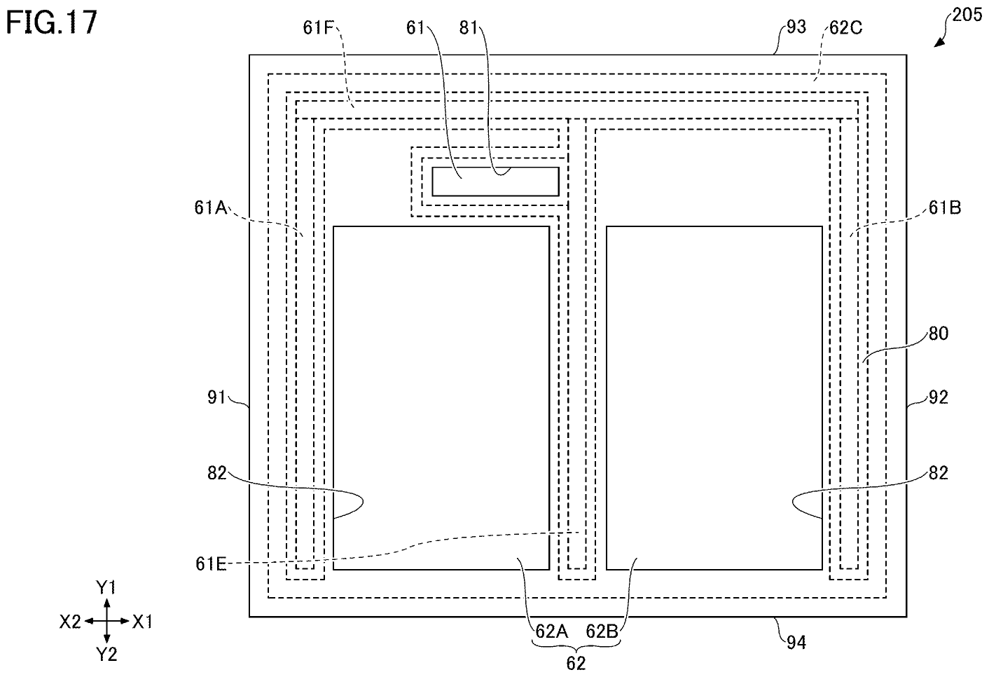

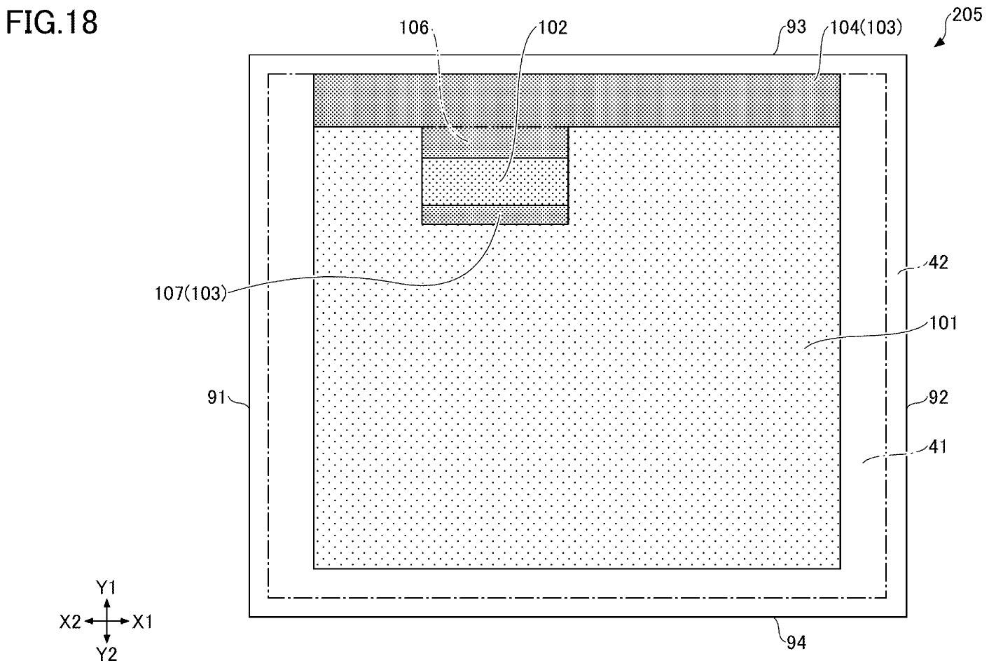

Next, a fifth embodiment will be described. The fifth embodiment differs from the fourth embodiment mainly in the arrangement of the gate pad 61. FIG. 17 is a top view illustrating a silicon carbide semiconductor device according to the fifth embodiment. FIG. 18 is a diagram illustrating respective regions in a silicon carbide substrate in the silicon carbide semiconductor device according to the fifth embodiment.

As illustrated in FIGS. 17 and 18, a MOSFET 205 according to the fifth embodiment does not include the gate runner 61G, and the gate runner 61E is connected to the gate runner 61F. In addition, the gate pad 61 is provided on the X2 side of the gate runner 61E, and is not provided on the X1 side. As in the fourth embodiment, the contact hole 72 includes the contact hole 76 reaching the contact region 34 between the gate pad 61 and the gate runner 61F in plan view (see FIG. 16).

The other elements are substantially the same as in the fourth embodiment.

The fifth embodiment also brings substantially the same effects as in the fourth embodiment.

### Sixth Embodiment

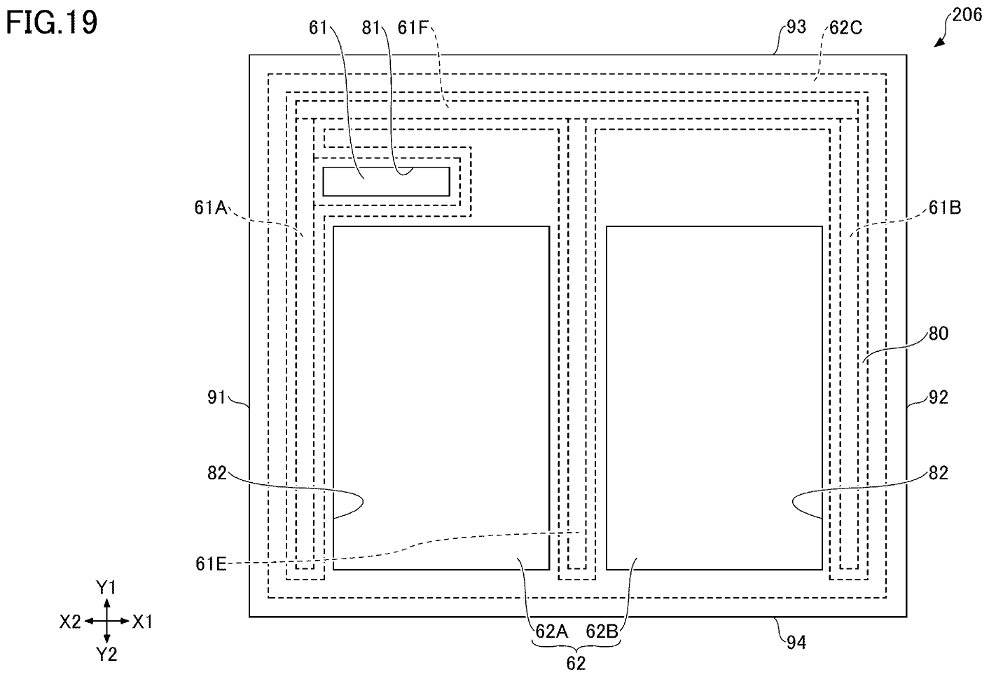

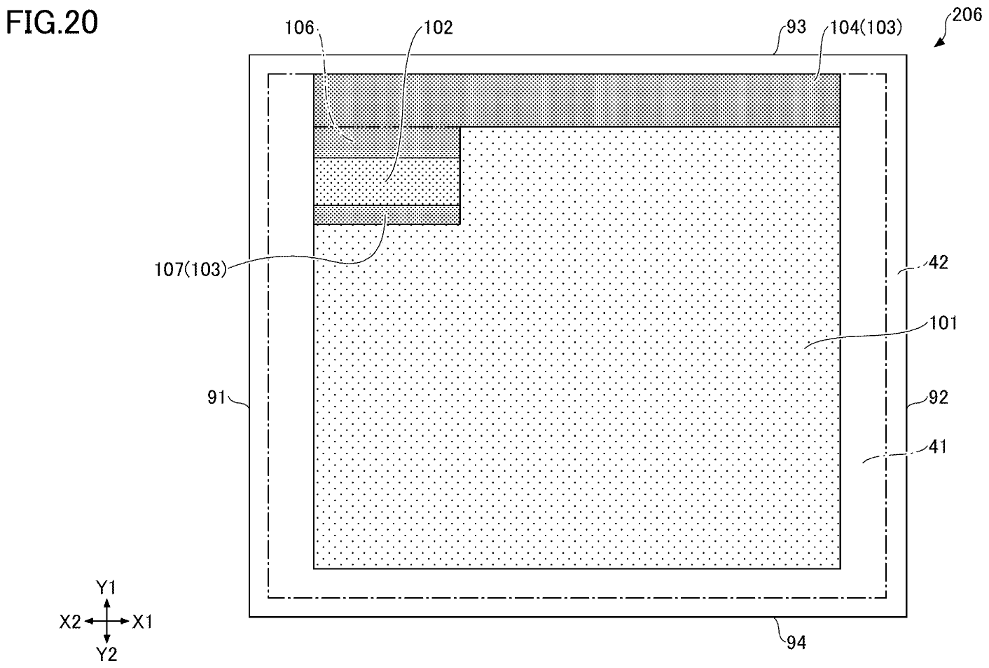

Next, a sixth embodiment will be described. The sixth embodiment differs from the fifth embodiment mainly in the arrangement of the gate pad 61. FIG. 19 is a top view illustrating a silicon carbide semiconductor device according to the sixth embodiment. FIG. 20 is a diagram illustrating respective regions in a silicon carbide substrate in the silicon carbide semiconductor device according to the sixth embodiment.

As illustrated in FIGS. 19 and 20, in a MOSFET 206 according to the sixth embodiment, the gate pad 61 is in contact with the gate runner 61A, not with the gate runner 61E. As in the fourth embodiment, the contact hole 72 includes the contact hole 76 reaching the contact region 34 between the gate pad 61 and the gate runner 61F in plan view (see FIG. 16).

The other elements are substantially the same as in the fifth embodiment.

The sixth embodiment also brings substantially the same effects as in the fifth embodiment.

### Seventh Embodiment

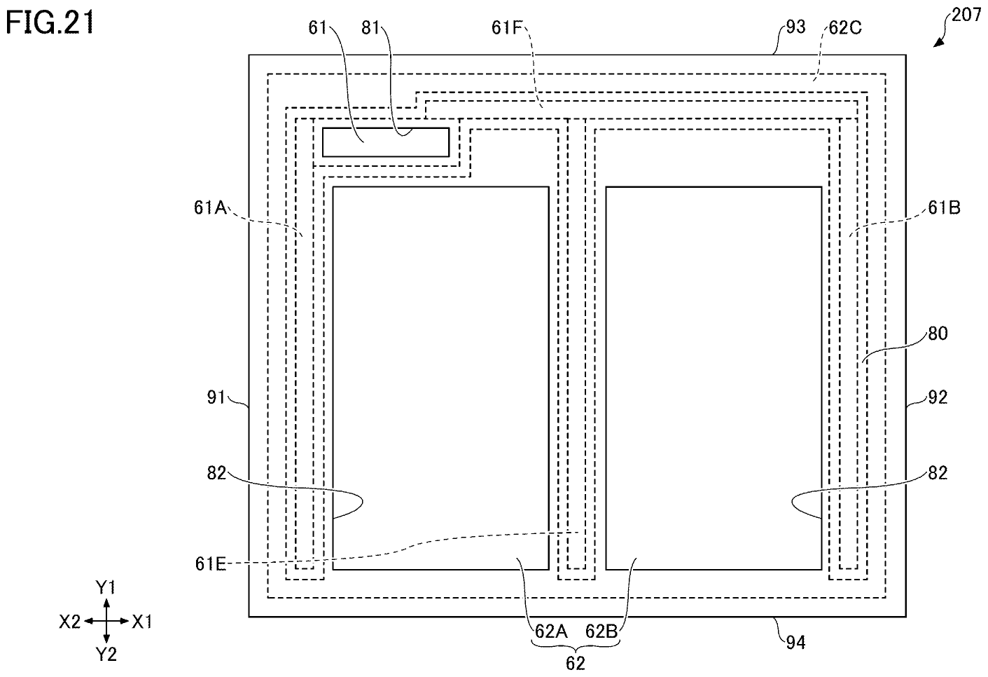

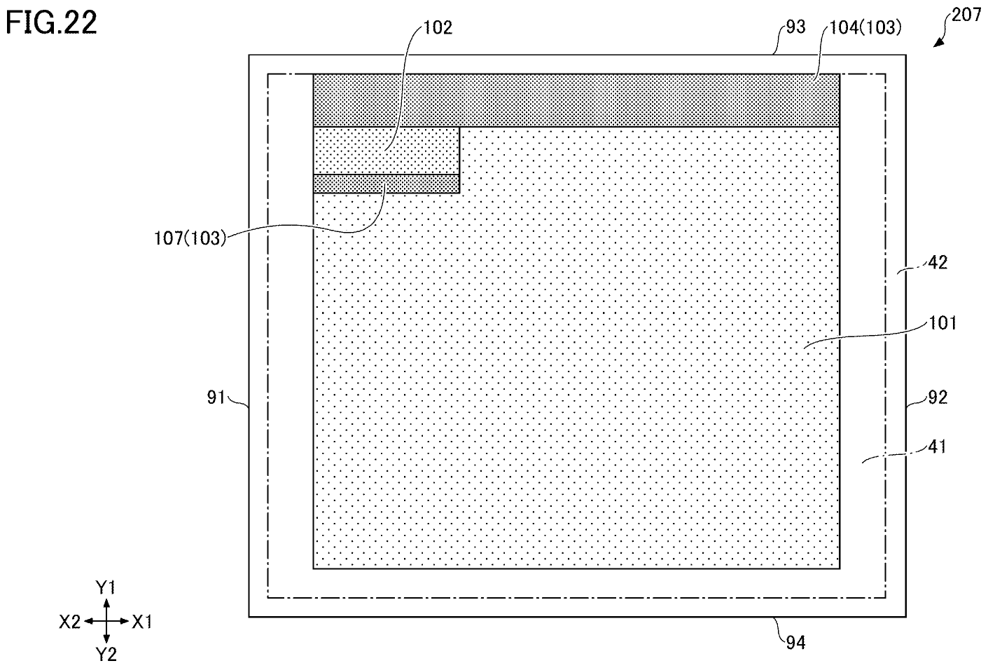

Next, a seventh embodiment will be described. The seventh embodiment differs from the sixth embodiment mainly in the arrangement of the gate pad 61. FIG. 21 is a top view illustrating a silicon carbide semiconductor device according to the seventh embodiment. FIG. 22 is a diagram illustrating respective regions in a silicon carbide substrate in the silicon carbide semiconductor device according to the seventh embodiment.

As illustrated in FIGS. 21 and 22, in a MOSFET 207 according to the seventh embodiment, the gate pad 61 is in contact with the gate runners 61E and 61A. The gate pad 61 is arranged on the Y2 side relative to the gate runner 61F. Therefore, the gate pad 61 does not exist on the X2 side of the gate runner 61F. On the X2 side of the gate runner 61F, the dimension of the contact hole 73 in the short direction is greater than the dimension of the short direction in other parts. Note that the contact hole 72 may not include the contact hole 76.

The other elements are substantially the same as in the sixth embodiment.

The seventh embodiment also brings substantially the same effects as in the sixth embodiment.

### Eighth Embodiment

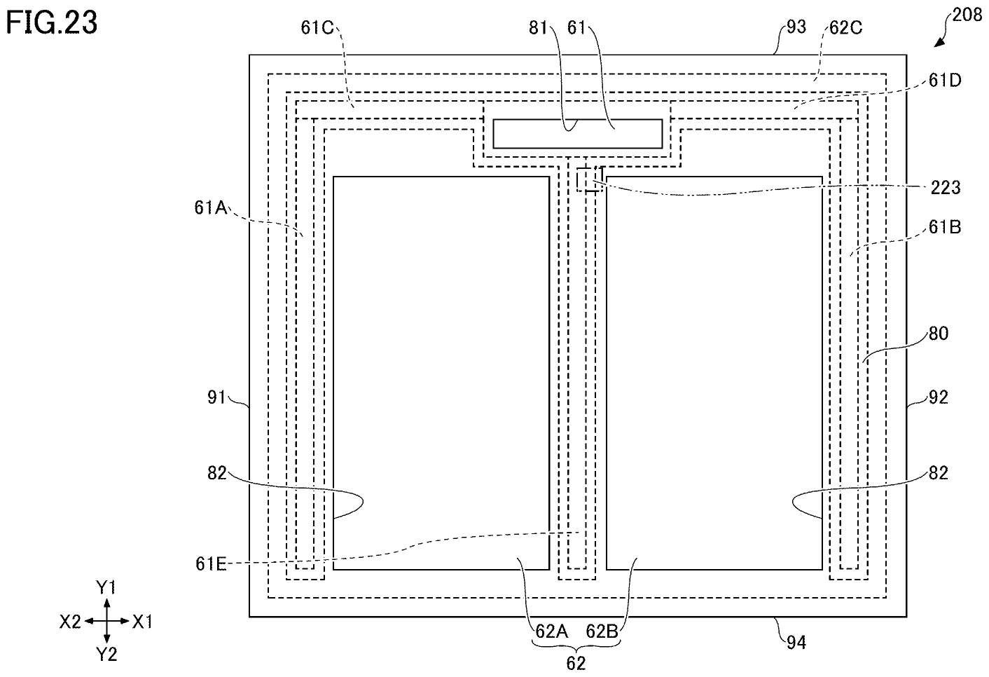

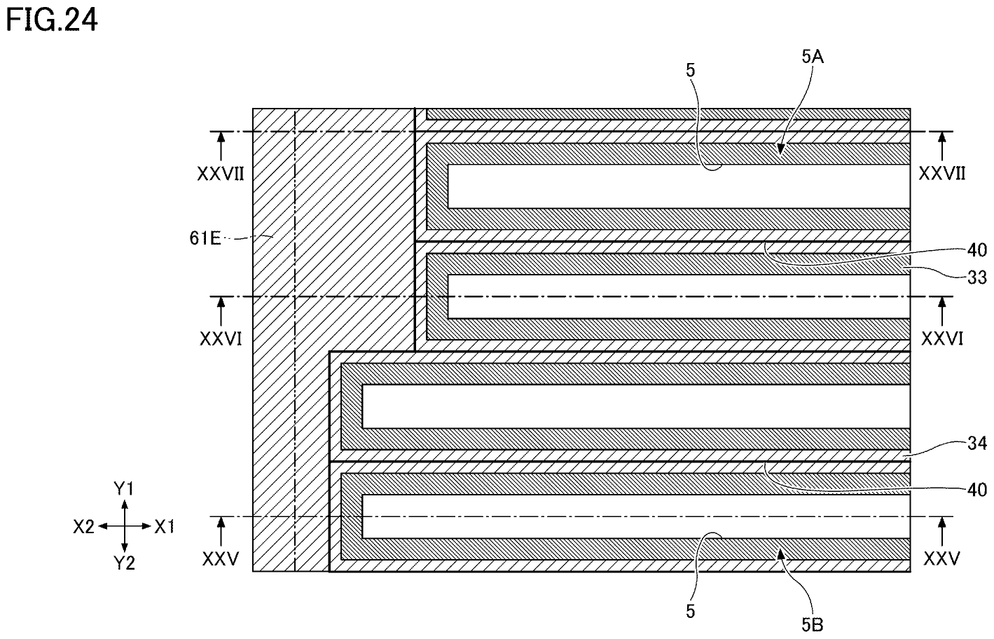

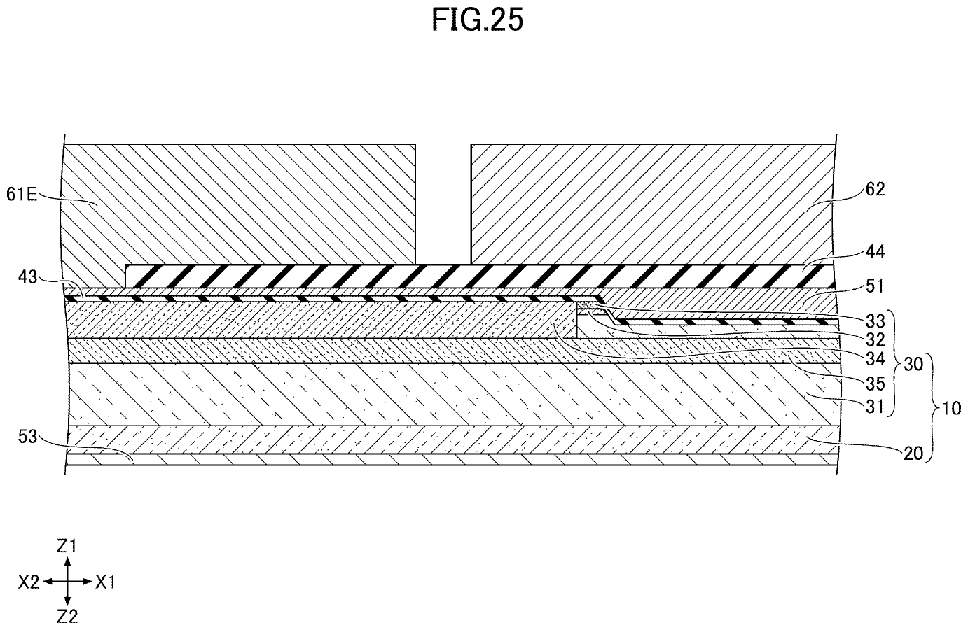

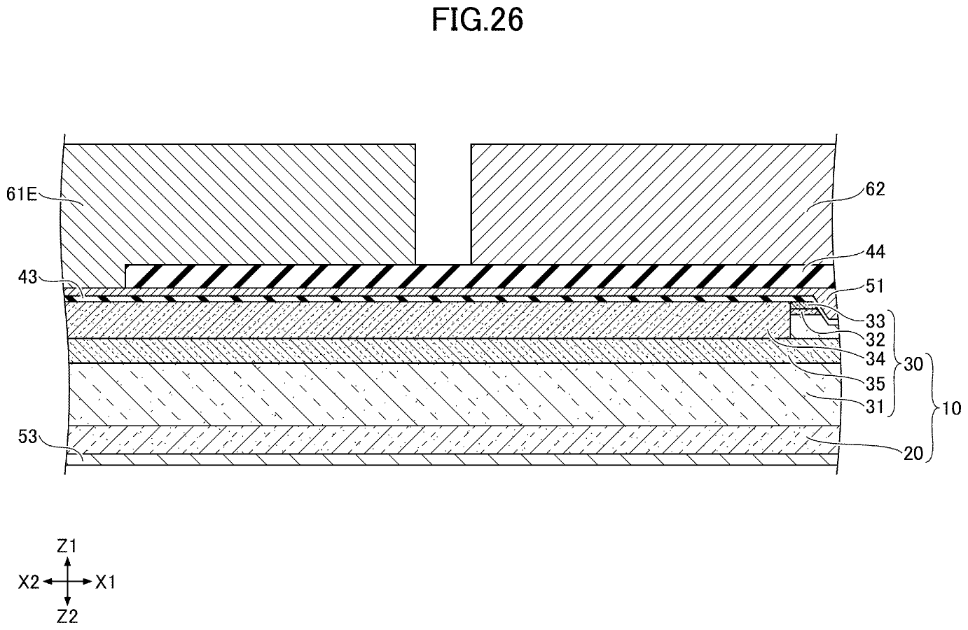

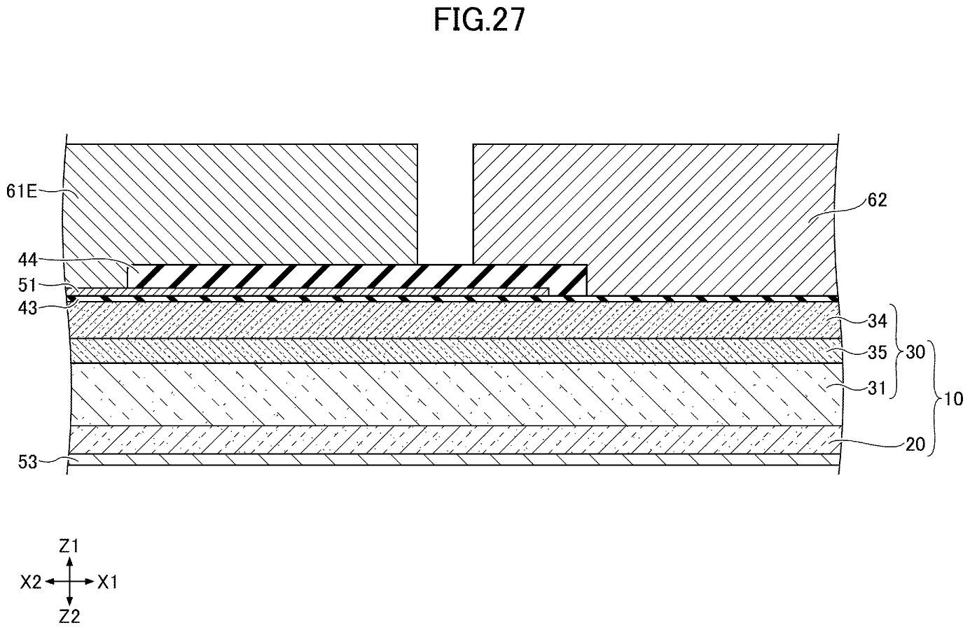

Next, an eighth embodiment will be described. The eighth embodiment differs from the first embodiment primarily in the configuration of the contact region 34 on the Y2 side of the second region 102. FIG. 23 is a top view illustrating a silicon carbide semiconductor device according to the eighth embodiment. FIG. 24 is a top view illustrating a configuration of the first principal surface of a silicon carbide substrate in a region 223 in FIG. 23. FIGS. 25 to 27 are cross-sectional views illustrating the silicon carbide semiconductor device according to the eighth embodiment. FIG. 25 corresponds to a cross-sectional view along a line XXV-XXV in FIG. 24. FIG. 26 corresponds to a cross-sectional view along a line XXVI-XXVI in FIG. 24. FIG. 27 corresponds to a cross-sectional view along a line XXVII-XXVII in FIG. 24. In FIGS. 25 to 27, the passivation film is omitted.

As illustrated in FIGS. 23 to 27, in a MOSFET 208 according to the eighth embodiment, among multiple unit cells 40 positioned closer to the fourth side 94 as compared to the seventh region 107, some of the unit cells 40 positioned closer to the third side 93 are further away from the gate runner 61E in the X1-X2 direction as compared to the other unit cells 40. For example, at a position closer to the fourth side 94 as compared to the seventh region 107 (the Y2 side), among the multiple gate trenches 5 aligned in the Y1-Y2 direction, a first trench group 5A of some of the gate trenches 5 positioned on the Y1 side is further away from the gate runner 61E in plan view as compared to a second trench group 5B of the other gate trenches 5 positioned on the Y2 side relative to the first trench group 5A. In plan view, a dimension in the X1-X2 direction of the contact region 34 between the first trench group 5A and the gate runner 61E is greater than a dimension in the X1-X2 direction of the contact region 34 between the second trench group 5B and the gate runner 61E.

The other elements are substantially the same as in the first embodiment.

The eighth embodiment also brings substantially the same effects as in the first embodiment. In addition, according to the eighth embodiment, the electric field concentration in the interlayer insulating film 44 in the vicinity of the gate runner 61E of the first trench group 5A can be reduced.

### Modified Example of First Region

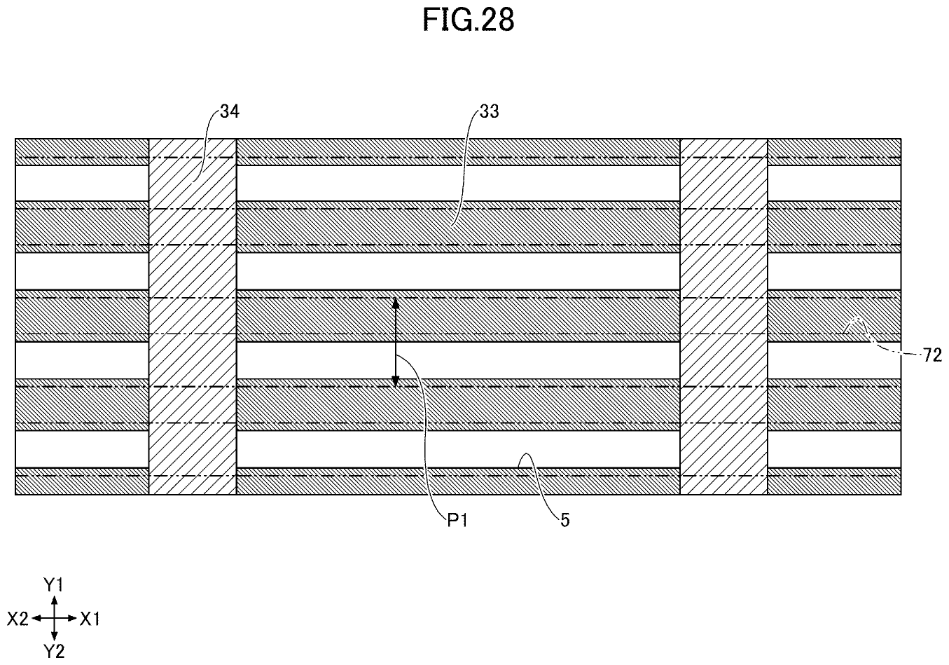

Here, a modified example of the first region will be described. In this modified example, the configuration of the unit cell is different from that of the first embodiment. FIG. 28 is a top view illustrating the modified example of the first region. As in FIG. 4, FIG. 28 illustrates the configuration of the first principal surface of the silicon carbide substrate.

In this modified example, in the first region 101, multiple gate trenches 5 are formed between two adjacent gate runners in the X1-X2 direction. In addition, in the first region 101, the contact region 34 is provided between the adjacent gate trenches 5 in the X1-X2 direction and extends in the Y1-Y2 direction.

As above, embodiments have been described in detail, but are not limited to specific embodiments, and may be modified and changed in various ways within the scope described in the claims.

### LIST OF REFERENCE NUMERALS

1 first principal surface
2 second principal surface
3 side surface
4 bottom surface
5 gate trench
5A first trench group
5B second trench group
10 silicon carbide substrate
20 silicon carbide single-crystal substrate
30 silicon carbide epitaxial layer
31 drift region
32 body region
33 source region
34 contact region
35 embedded region
36 embedded JTE region
37 surface JTE region (third semiconductor region)
40 unit cell
41 active region
42 terminal region
43 gate insulation film
44 interlayer insulation film
45 field insulation film
51 gate electrode
52 contact electrode
53 drain electrode
61 gate pad
61A, 61B, 61C, 61D, 61E, 61F, 61G gate runner
62, 62A, 62B source pad
62C source runner
63 gate insulation film
64 side surface
70, 71, 72, 73, 74, 75, 76, 77 contact hole
80 passivation film
81, 82 opening
91 first side
92 second side
93 third side
94 fourth side
101 first region
102 second region
103 third region
104 fourth region
105 fifth region
106 sixth region
107 seventh region
111 first semiconductor region
112 second semiconductor region
113 third semiconductor region
114 fourth semiconductor region
115 fifth semiconductor region
116 sixth semiconductor region
117 seventh semiconductor region
201, 202, 203, 204, 205, 206, 207, 208 MOSFET
221, 222, 223 region

1. A silicon carbide semiconductor device comprising:
a silicon carbide substrate having a first principal surface;
an interlayer insulating film covering the first principal surface; and
a gate pad and a source pad provided on the interlayer insulating film,
wherein the silicon carbide substrate includes, in plan view in a direction perpendicular to the first principal surface,
a first region including a plurality of unit cells,
a second region overlapping the gate pad, and
a third region contiguous to the second region,
wherein each of the plurality of unit cells includes
a drift region having a first conductive type,
a body region having a second conductive type different from the first conductive type,
a source region provided on the first principal surface, separated from the drift region by the body region, and having the first conductive type,
a contact region provided on the first principal surface, electrically connected to the body region, and having the second conductive type,
a gate electrode electrically connected to the gate pad, and
a gate insulating film provided between the gate electrode and the drift region, the body region, and the source region,
wherein the second region includes a first semiconductor region having the second conductive type,
wherein the third region includes a second semiconductor region having the second conductive type,
wherein the first semiconductor region and the second semiconductor region are contiguous to each other on the first principal surface,
wherein, in the interlayer insulation film, a first contact hole reaching the source region and the contact region, and a second contact hole reaching the second semiconductor region are formed, and
wherein the source pad is electrically connected to the source region and the contact region via the first contact hole,
electrically connected to the second semiconductor region via the second contact hole, and
in a cross section as viewed in a direction parallel to the first principal surface, a dimension in a short direction of the second contact hole is greater than a dimension in a short direction of the first contact hole.

2. The silicon carbide semiconductor device as claimed in claim 1, wherein the contact region and the second semiconductor region are contiguous to each other on the first principal surface.

3. The silicon carbide semiconductor device as claimed in claim 1, further comprising:
an active region including the plurality of unit cells; and
a terminal region provided around the active region,
wherein the terminal region includes a third semiconductor region having the second conductive type,
wherein, in plan view in a direction perpendicular to the first principal surface, the second semiconductor region is provided between the gate pad and the terminal region, and includes a fourth semiconductor region contiguous to the first semiconductor region and the third semiconductor region on the first principal surface,
wherein a concentration of impurities of the second conductivity type in the third semiconductor region is lower than a concentration of impurities of the second conductivity type in the fourth semiconductor region, and
wherein the second contact hole includes a third contact hole reaching the fourth semiconductor region.

4. The silicon carbide semiconductor device as claimed in claim 3, further comprising:
a field insulating film provided between the interlayer insulating film and the first semiconductor region, the fourth semiconductor region, and the third semiconductor region,
wherein a fourth contact hole reaching the fourth semiconductor region is formed in the field insulating film,
wherein the interlayer insulation film is in contact with the fourth semiconductor region inside the fourth contact hole, and
wherein the third contact hole is positioned inside the fourth contact hole.

5. The silicon carbide semiconductor device as claimed in claim 3, further comprising:
a source runner electrically connected to the source pad, and electrically connected to the fourth semiconductor region through the third contact hole,
wherein, in a cross section as viewed in a direction parallel to the first principal surface, a side surface of the source runner on a side away from the gate pad is positioned on a boundary line between the third semiconductor region and the fourth semiconductor region, or positioned closer to the gate pad as compared to the boundary line.

6. The silicon carbide semiconductor device as claimed in claim 3, further comprising:
a first gate runner electrically connected to the gate pad, extending in a first direction parallel to the first principal surface, and arranged closer to the terminal region as compared to the gate pad; and
a second gate runner electrically connected to the gate pad, extending in the first direction, being separated from the first gate runner, and arranged closer to the terminal region as compared to the gate pad,
wherein, in plan view in a direction perpendicular to the first principal surface, the fourth semiconductor region is provided between the first gate runner and the second gate runner, and includes a fifth semiconductor region contiguous to the first semiconductor region on the first principal surface, and
wherein the second contact hole includes a fifth contact hole reaching the fifth semiconductor region.

7. The silicon carbide semiconductor device as claimed in claim 3, further comprising:
a third gate runner electrically connected to the gate pad, extending in a first direction parallel to the first principal surface, and arranged closer to the terminal region as compared to the gate pad,
wherein, in plan view in a direction perpendicular to the first principal surface, the fourth semiconductor region is provided between the gate pad and the third gate runner, and includes a sixth semiconductor region contiguous to the first semiconductor region on the first principal surface, and
wherein the second contact hole includes a sixth contact hole reaching the sixth semiconductor region.

8. The silicon carbide semiconductor device as claimed in claim 3, wherein the plurality of unit cells extend in a first direction parallel to the first principal surface, and are arrayed in a second direction perpendicular to the first direction,
wherein the gate pad has, in plan view in a direction perpendicular to the first principal surface, a rectangular planar shape with the first direction as a longitudinal direction,
wherein the second semiconductor region includes a seventh semiconductor region provided at a position sandwiching the gate pad with the fourth semiconductor region in the second direction, and
the second contact hole includes a seventh contact hole reaching a seventh semiconductor region.

9. The silicon carbide semiconductor device as claimed in claim 8, wherein, in a cross section as viewed in a direction parallel to the first principal surface, a third dimension in a short direction of the third contact hole is equal to a fourth dimension in a short direction of the seventh contact hole.

10. The silicon carbide semiconductor device as claimed in claim 8, wherein a fifth dimension in the first direction of the third contact hole is greater than a sixth dimension in the first direction of the gate pad.

11. The silicon carbide semiconductor device as claimed in claim 8, wherein, in plan view, the silicon carbide substrate has a rectangular shape having a first side and a second side parallel to each other, and a third side and a fourth side perpendicular to the first side and the second side,
further comprising:
a fourth gate runner extending along the first side;
a fifth gate runner extending along the second side; and
a sixth gate runner extending from the gate pad toward the fourth side between the fourth gate runner and the fifth gate runner,
wherein the fourth gate runner, the fifth gate runner, and the sixth gate runner are electrically connected to the gate pad.

12. The silicon carbide semiconductor device as claimed in claim 11, wherein a seventh dimension in the first direction of part of the seventh contact hole between the fourth gate runner and the sixth gate runner in plan view is greater than or equal to ½ of a distance between the fourth gate runner and the sixth gate runner.

13. The silicon carbide semiconductor device as claimed in claim 11, wherein an eighth dimension in the first direction of a part of the seventh contact hole between the fifth gate runner and the sixth gate runner in plan view is greater than or equal to ½ of a distance between the fifth gate runner and the sixth gate runner.

14. The silicon carbide semiconductor device as claimed in claim 11, wherein, among a plurality of unit cells positioned closer to the fourth side as compared to the seventh semiconductor region, part of the unit cells positioned close to the third side are further away from the sixth gate runner in the second direction as compared to other unit cells.
